(19) United States
(12) Patent Application Publication
(10) Pub. No.: US 2024/0372570 A1
(43) Pub. Date: Nov. 7, 2024

(54) SEMICONDUCTOR DEVICE

(71) Applicant: Sony Semiconductor Solutions Corporation, Kanagawa (JP)

(72) Inventor: Tomohiro Matsumoto, Kanagawa (JP)

(21) Appl. No.: 18/293,056

(22) PCT Filed: Mar. 3, 2022
(86) PCT No.: PCT/JP22/09163

§ 371 Date: Jan. 29, 2024

(30) Foreign Application Priority Data
Sep. 16, 2021 (JP) 2021-151594

(51) Int. Cl. H04B 1/04; H01L 27/146; H04N 25/76

(52) U.S. Cl. CPC H04B 1/04; H01L 27/14649; H04N 25/7795

(57) ABSTRACT

A semiconductor device of the present disclosure includes a light detector that includes a plurality of light-receiving pixels configured to detect light, a phase synchronizing circuit configured to generate an AC signal, a modulation circuit configured to modulate the AC signal by controlling an operation of the phase synchronizing circuit, a wired transmission circuit configured to transmit a result of the detection by the light detector by using the AC signal as a clock signal, and a wireless transmission circuit configured to transmit the AC signal modulated by the modulation circuit.

### TECHNICAL FIELD

The present disclosure relates to a semiconductor device that detects light.

### BACKGROUND ART

Some semiconductors detect light, such as an image sensor or a ToF (Time of Flight) sensor, for example. Such a light-detecting semiconductor device includes a semiconductor device that allows for wireless communication (for example, PTL 1).

### CITATION LIST

### Patent Literature

PTL 1: International Publication No. WO2006/090744

### SUMMARY OF THE INVENTION

A semiconductor device is desired to have a smaller circuit area, and a further reduction in circuit area is expected.

It is desirable to provide a semiconductor device that allows for a reduction in circuit area.

A semiconductor device according to one embodiment of the present disclosure includes a light detector, a phase synchronizing circuit, a modulation circuit, a wired transmission circuit, and a wireless transmission circuit. The light detector includes a plurality of light-receiving pixels configured to detect light. The phase synchronizing circuit is configured to generate an AC signal. The modulation circuit is configured to modulate the AC signal by controlling an operation of the phase synchronizing circuit. The wired transmission circuit is configured to transmit a result of the detection by the light detector by using the AC signal as a clock signal. The wireless transmission circuit is configured to transmit the AC signal modulated by the modulation circuit.

In the semiconductor device in one embodiment of the present disclosure, the AC signal is generated by the phase synchronizing circuit. As a result of the operation of the phase synchronizing circuit being controlled by the modulation circuit, the AC signal is modulated. This AC signal is used as the clock signal in the wired transmission circuit. The light is detected by the light detector including the plurality of light-receiving pixels. The result of the detection by this light detector is transmitted by the wired transmission circuit. The AC signal modulated by the modulation circuit is transmitted by the wireless transmission circuit.

### BRIEF DESCRIPTION OF DRAWINGS

FIG. 1 is a block diagram illustrating a configuration example of a semiconductor device according to one embodiment of the present disclosure.

FIG. 2 is a block diagram illustrating a configuration example of a system including the semiconductor device illustrated in FIG. 1.

FIG. 3 describes a configuration example of a pixel array illustrated in FIG. 1.

FIG. 4 is a block diagram illustrating a configuration example of a PLL illustrated in FIG. 1.

FIG. 5 describes an example of a frequency in an AC signal generated by the PLL illustrated in FIG. 4.

FIG. 6 describes an example of the frequency in the AC signal generated by the PLL illustrated in FIG. 4.

FIG. 7 describes an example of an operation of the semiconductor device illustrated in FIG. 1.

FIG. 8 describes another example of the operation of the semiconductor device illustrated in FIG. 1.

FIG. 9 describes another example of the operation of the semiconductor device illustrated in FIG. 1.

FIG. 10 describes an example of a wireless communication operation of the semiconductor device illustrated in FIG. 1.

FIG. 11 describes another example of the wireless communication operation of the semiconductor device illustrated in FIG. 1.

FIG. 12 described another example of the wireless communication operation of the semiconductor device illustrated in FIG. 1.

FIG. 13 describes another example of the operation of the semiconductor device illustrated in FIG. 1.

FIG. 14 describes another example of the operation of the semiconductor device illustrated in FIG. 1.

FIG. 15 describes an example of a sensing operation of the semiconductor device illustrated in FIG. 1.

FIG. 16 is a block diagram illustrating a configuration example of a semiconductor device according to a modification example.

FIG. 17 is a block diagram illustrating a configuration example of a semiconductor device according to another modification example.

FIG. 18 is a block diagram illustrating a configuration example of a semiconductor device according to another modification example.

FIG. 19 describes an example of an operation of the semiconductor device illustrated in FIG. 18.

FIG. 20 describes an example of an operation of the semiconductor device illustrated in FIG. 18.

FIG. 21 describes another example of the operation of the semiconductor device illustrated in FIG. 18.

FIG. 22 describes another example of the operation of the semiconductor device illustrated in FIG. 18.

FIG. 23 is a block diagram illustrating a configuration example of a semiconductor device according to another modification example.

FIG. 24 is a block diagram illustrating a configuration example of a semiconductor device according to another modification example.

FIG. 25 is a block diagram illustrating a configuration example of a system including the semiconductor device illustrated in FIG. 24.

FIG. 26 is a block diagram illustrating a configuration example of a semiconductor device according to another modification example.

FIG. 28 is a block diagram illustrating a configuration example of a semiconductor device according to another modification example.

FIG. 28 is a block diagram illustrating a configuration example of a semiconductor device according to another modification example.

FIG. 29 is a circuit diagram illustrating a configuration example of a matching circuit in a wireless transmission circuit according to another modification example.

FIG. 30 is a circuit diagram illustrating a configuration example of a matching circuit in a wireless reception circuit according to another modification example.

FIG. 31 describes an implementation example of the matching circuit illustrated in FIGS. 29 and 30.

FIG. 32 describes a configuration example of an inductor illustrated in FIG. 31.

FIG. 33 is a circuit diagram illustrating a configuration example of a matching circuit in a wireless transmission circuit according to another modification example.

FIG. 34 describes an implementation example of the matching circuit illustrated in FIG. 33.

FIG. 35 is a circuit diagram illustrating a configuration example of a matching circuit in a wireless transmission circuit according to another modification example.

FIG. 36 describes an implementation example of the matching circuit illustrated in FIG. 35.

FIG. 37 is a circuit diagram illustrating a configuration example of an oscillation circuit according to another modification example.

FIG. 38 describes an implementation example of the oscillation circuit illustrated in FIG. 37.

FIG. 39 is a circuit diagram illustrating a configuration example of an oscillation circuit according to another modification example.

FIG. 40 describes an implementation example of the oscillation circuit illustrated in FIG. 39.

FIG. 41 is a circuit diagram illustrating a configuration example of an oscillation circuit according to another modification example.

FIG. 42 describes an implementation example of the oscillation circuit illustrated in FIG. 41.

FIG. 43 is a circuit diagram illustrating a configuration example of an inductor according to another modification example.

FIG. 44 is an external view illustrating an example of a smartphone to which the semiconductor device illustrated in FIG. 1 is applied.

FIG. 45 is a block diagram depicting an example of schematic configuration of a vehicle control system.

FIG. 46 is a diagram of assistance in explaining an example of installation positions of an outside-vehicle information detecting section and an imaging section.

### MODES FOR CARRYING OUT THE INVENTION

In the following, some embodiments of the disclosure will be described in detail with reference to the drawings. It is to be noted that the description will be given in the following order.
1. Embodiment
2. Application Example
3. Practical Application To Mobile Body

### 1. Embodiment

### Configuration Example

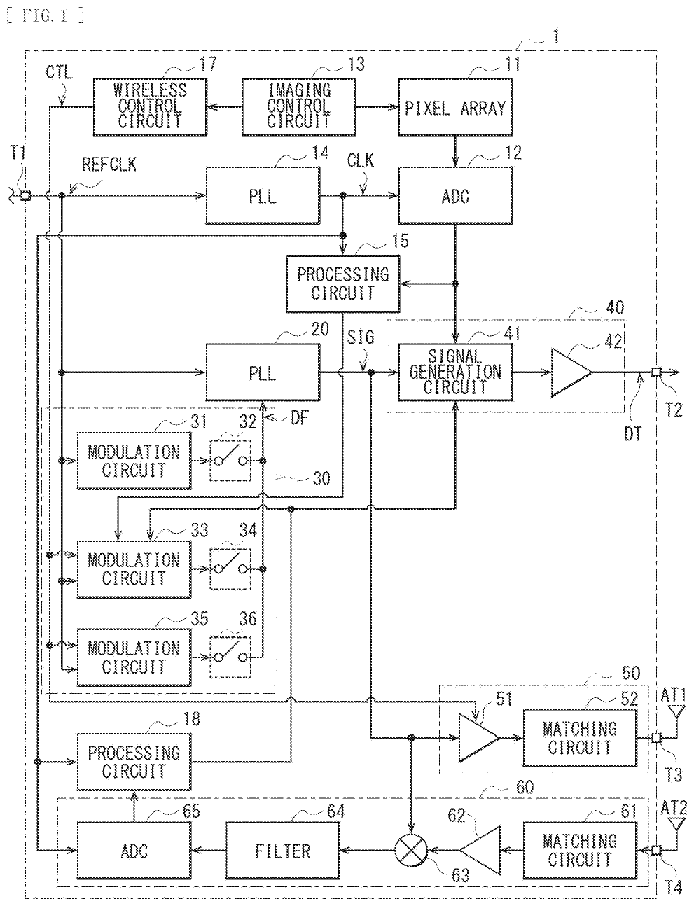

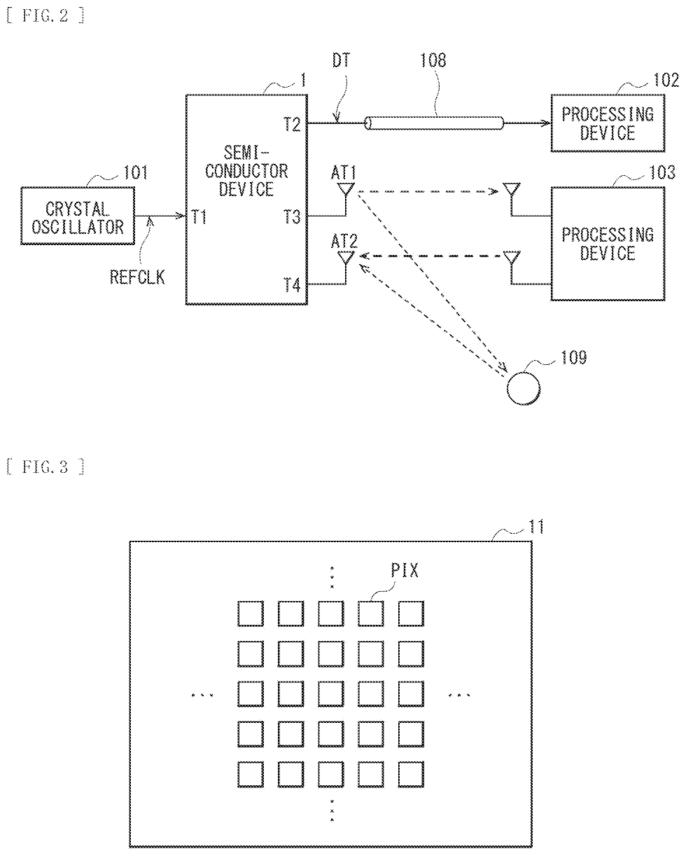

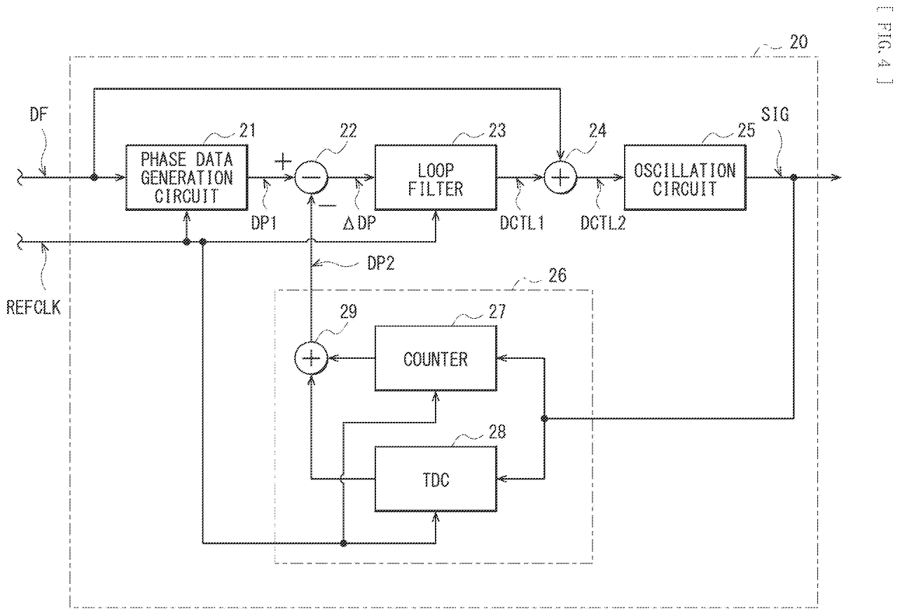

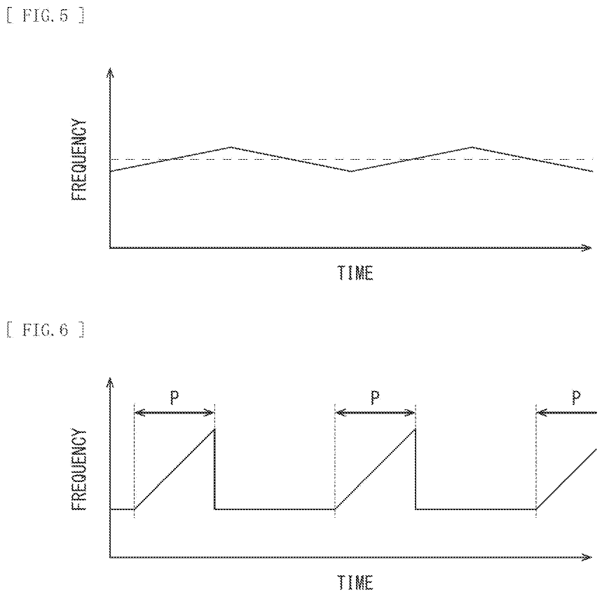

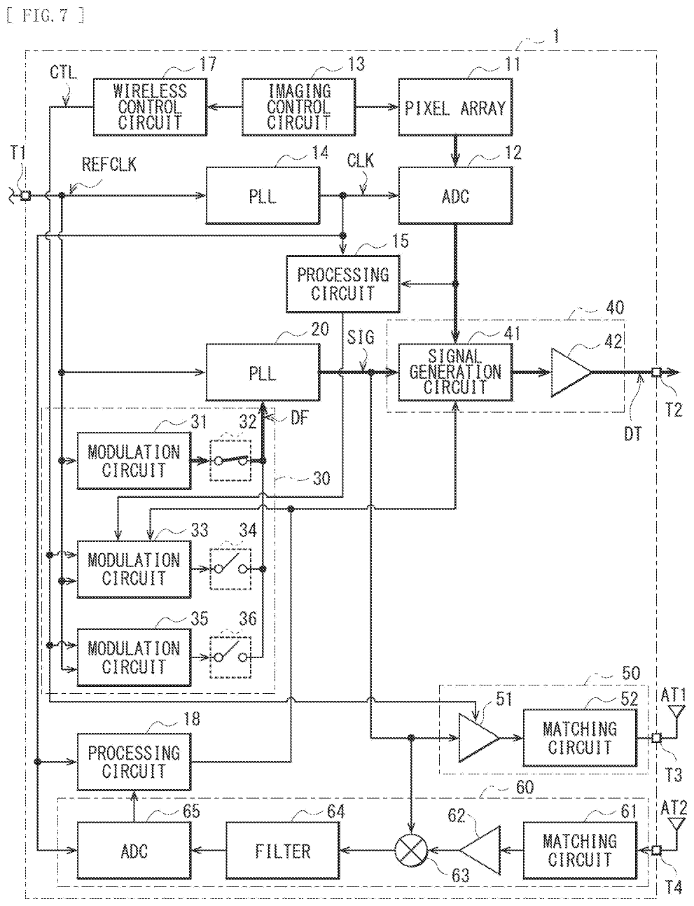

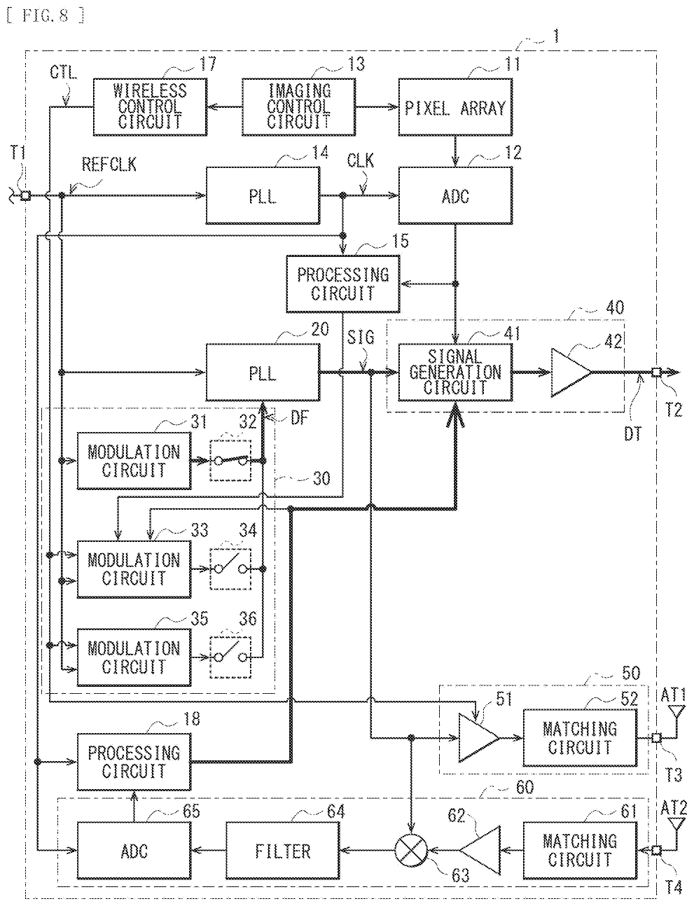

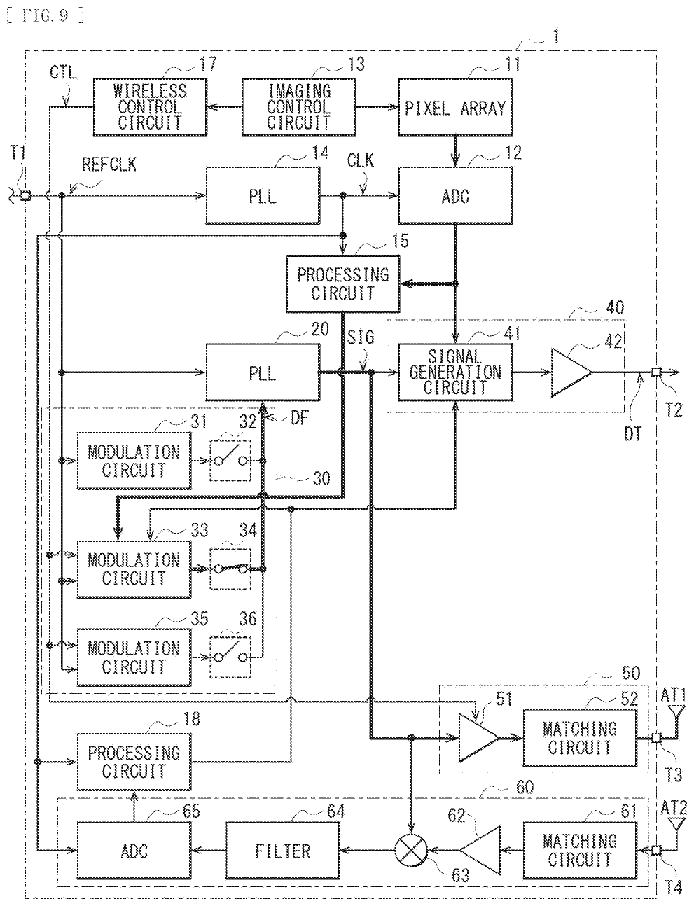

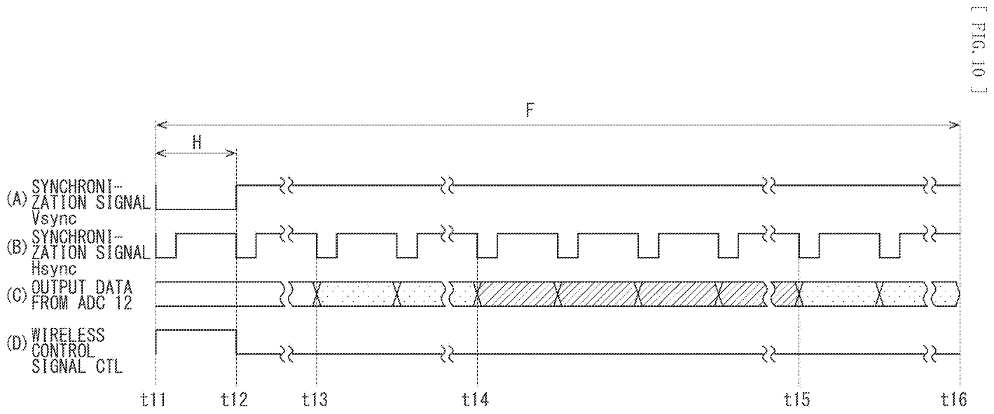

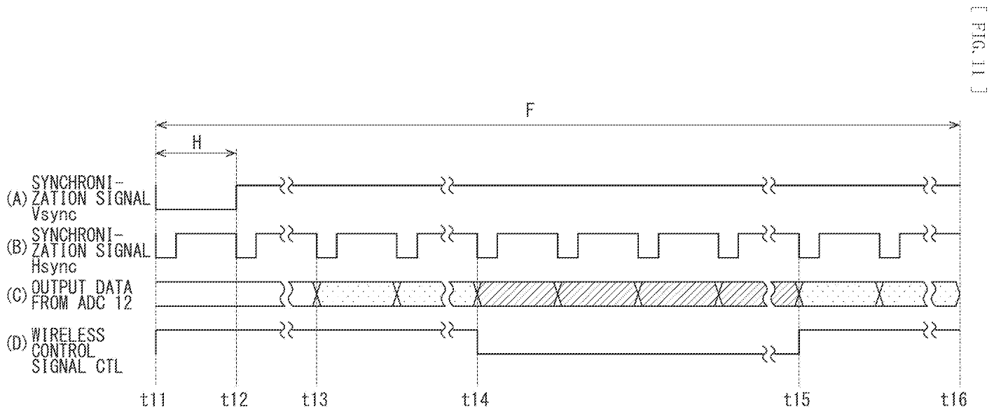

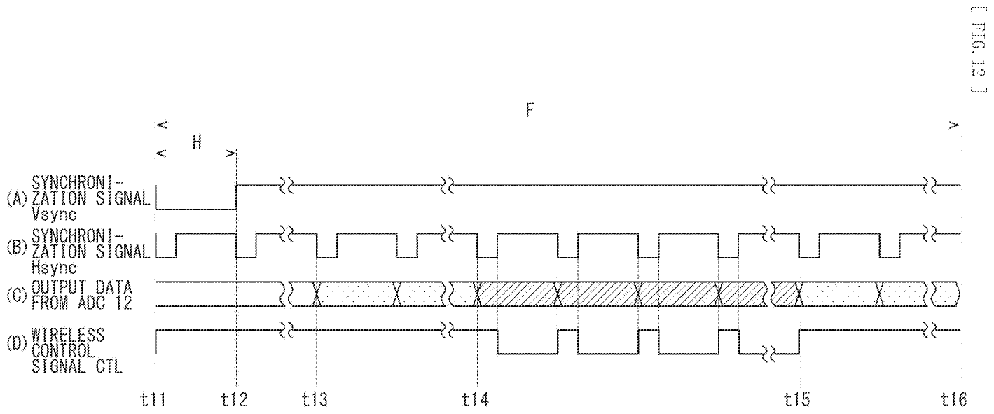

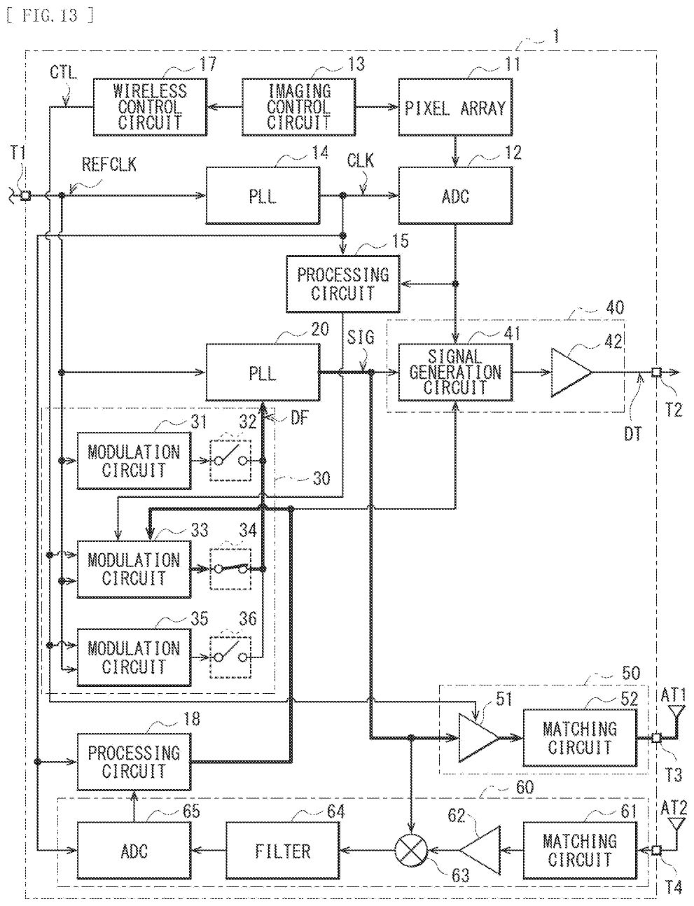

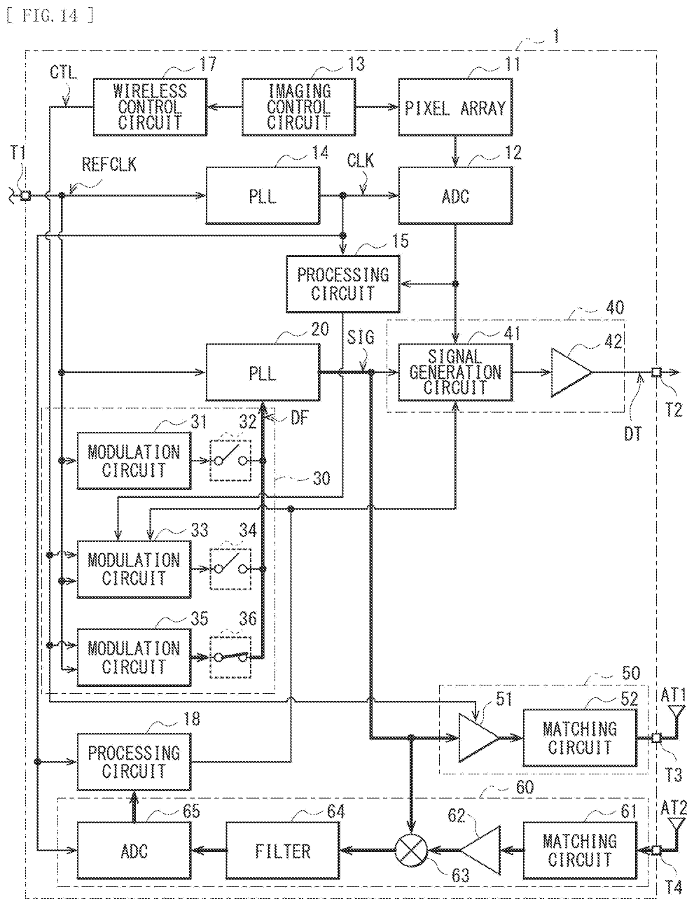

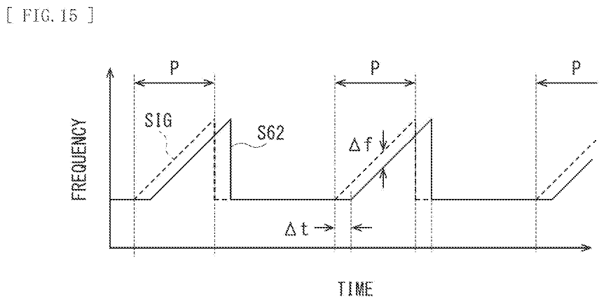

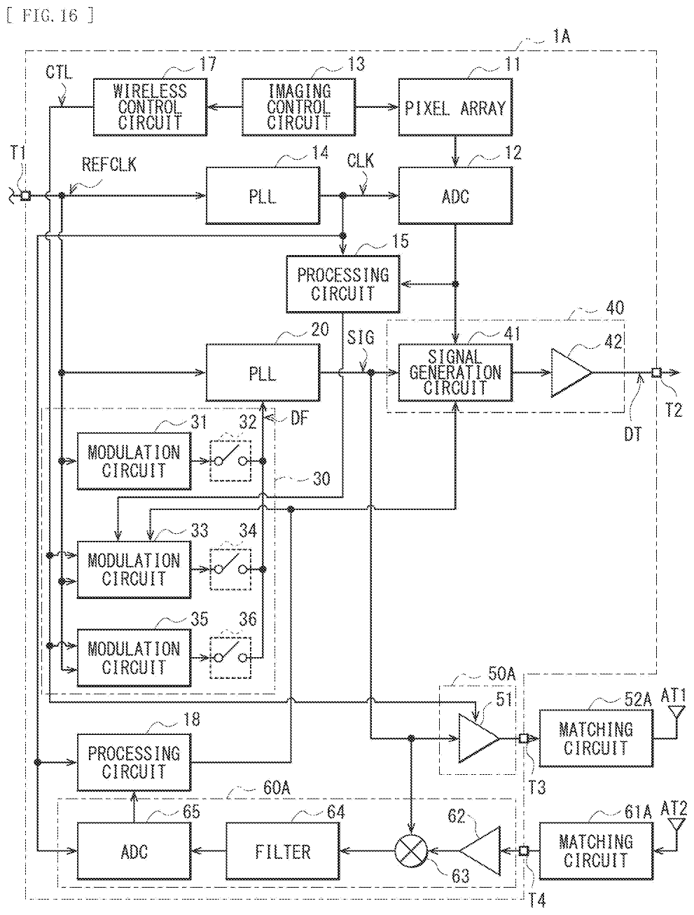

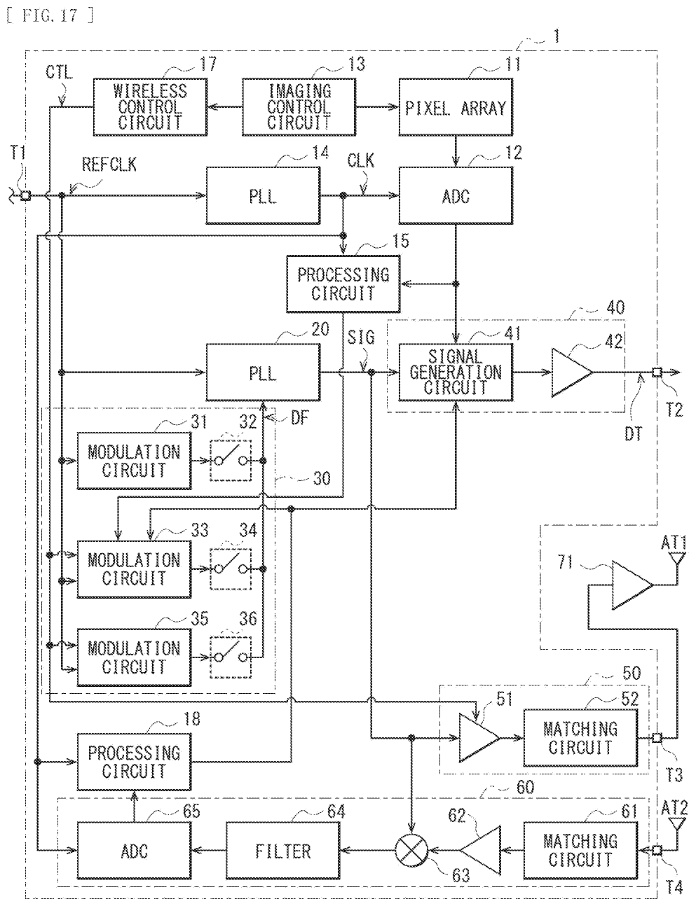

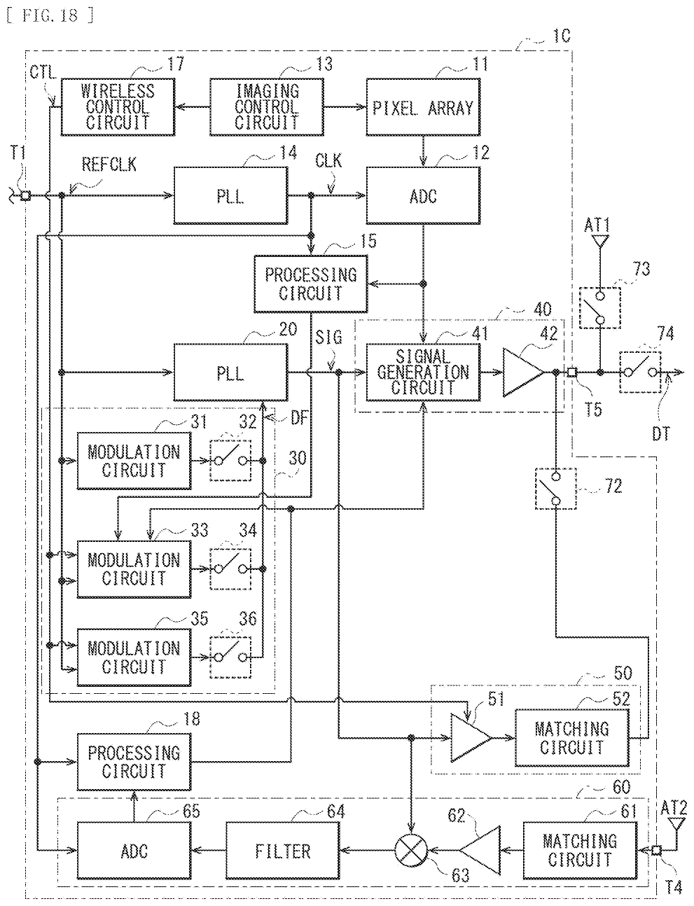

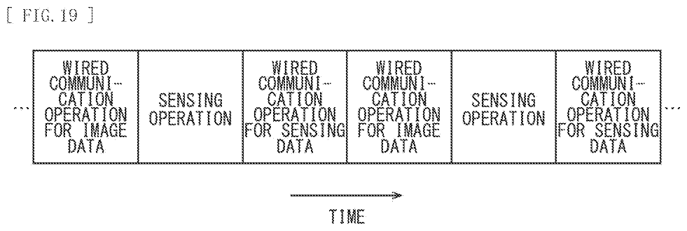

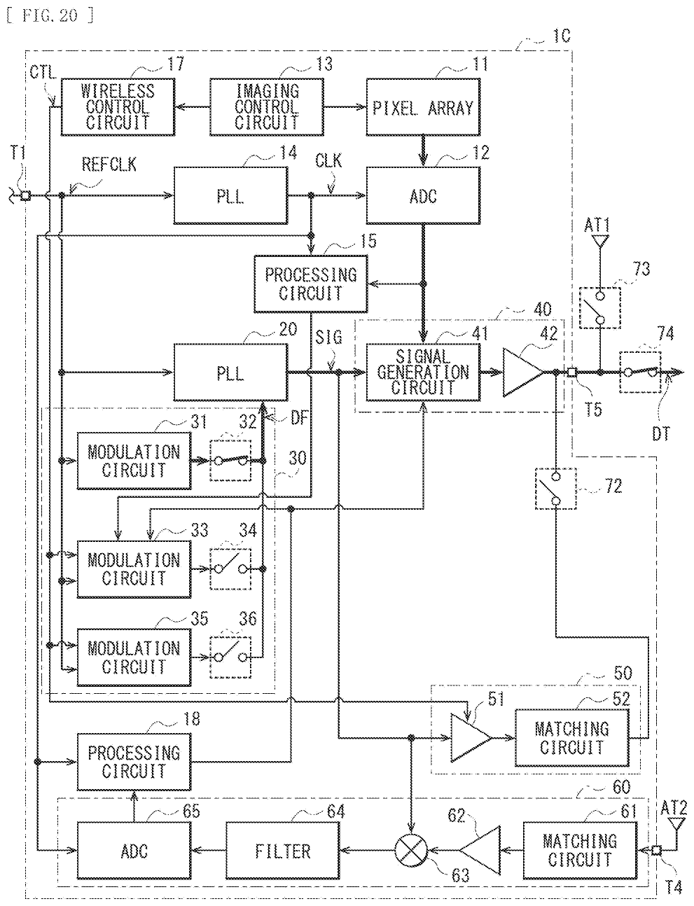

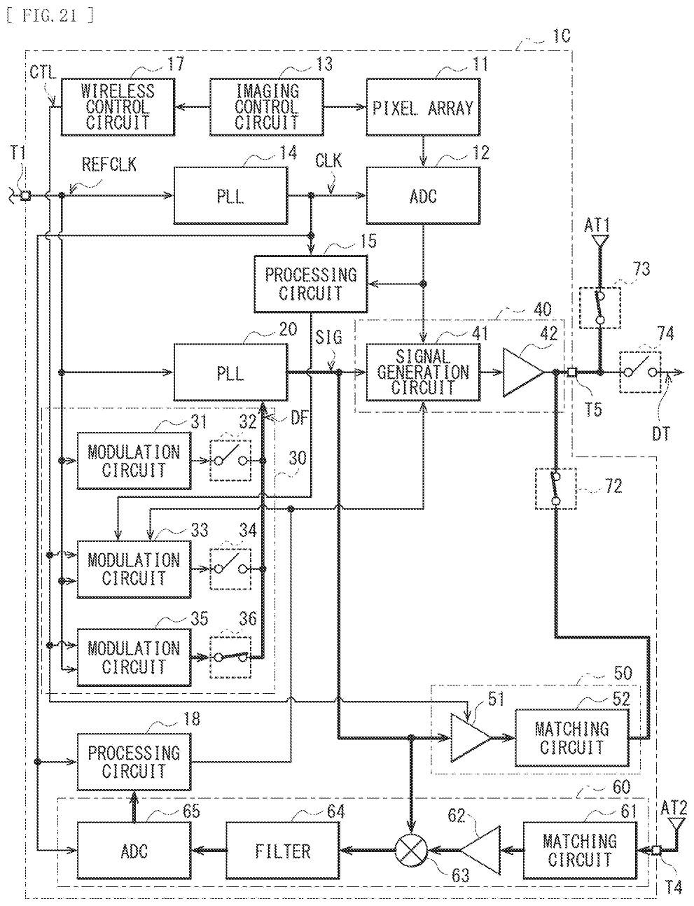

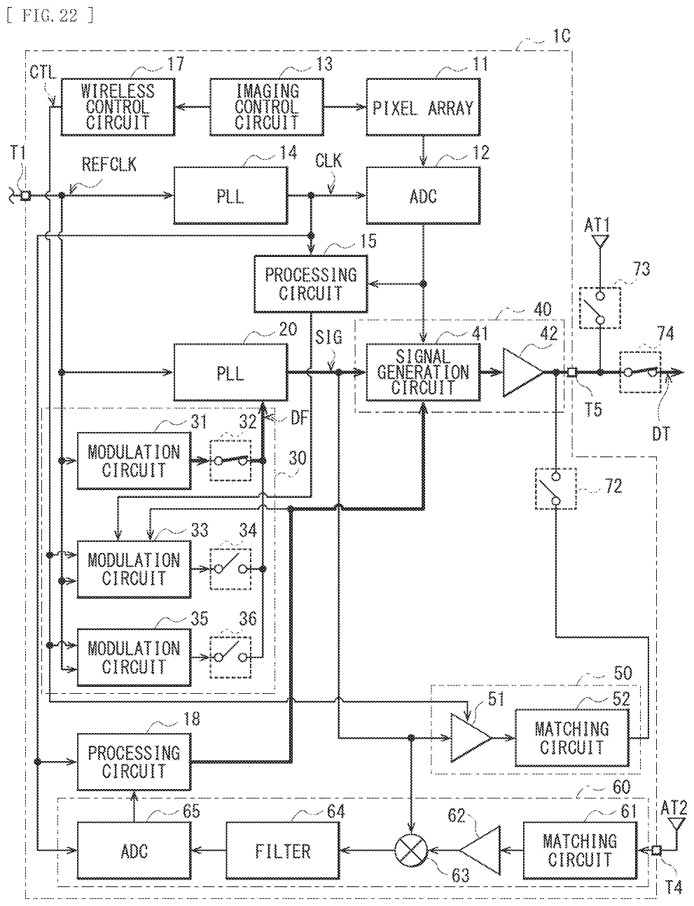

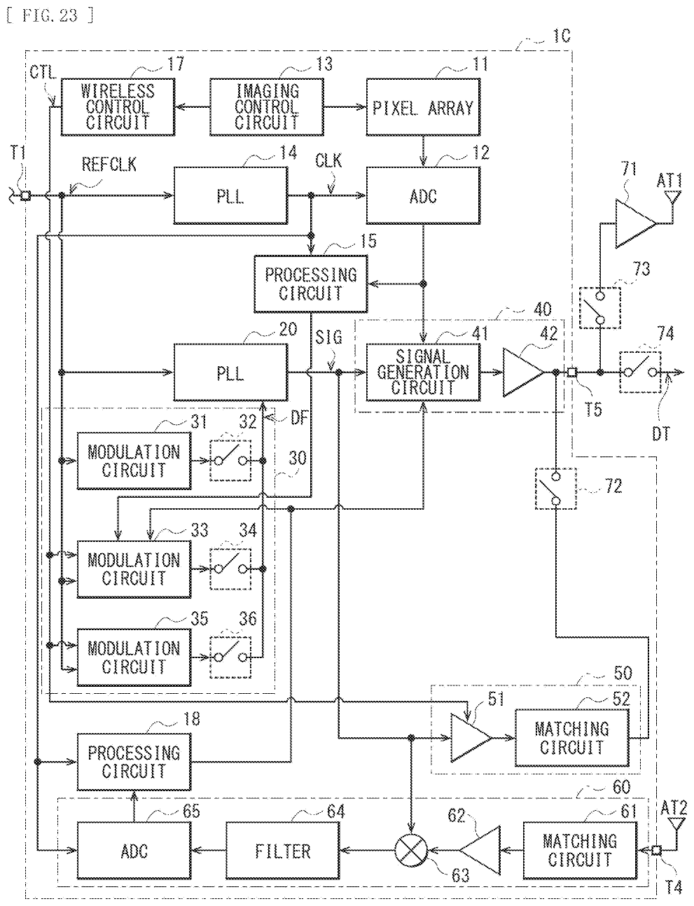

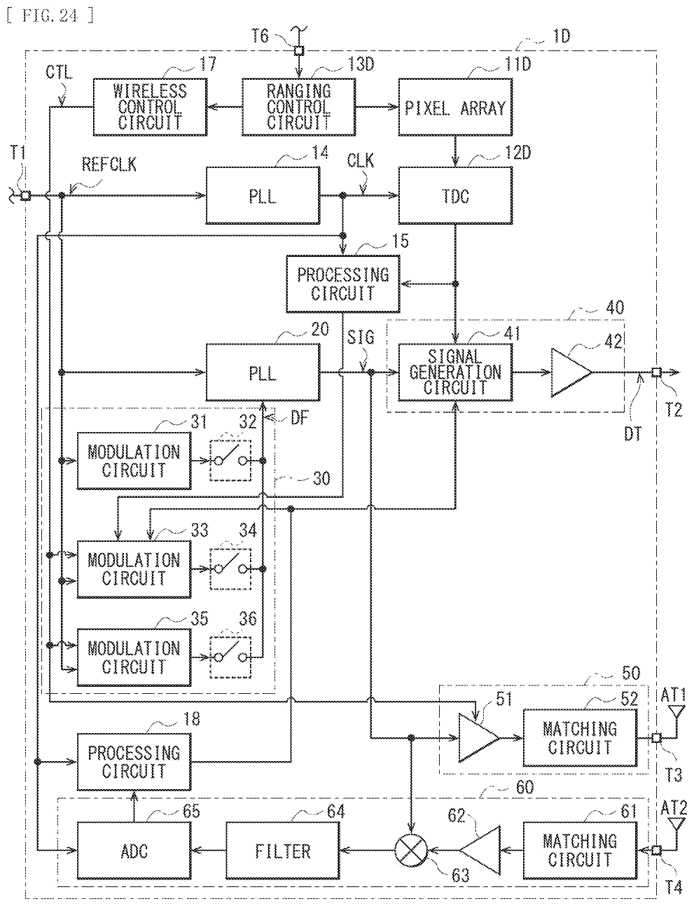

FIG. 1 illustrates a configuration example of a semiconductor device (semiconductor device 1) according to one embodiment. FIG. 2 illustrates a configuration example of a system including the semiconductor device 1. The semiconductor device 1 is configured to perform an imaging operation to capture an image of a subject while being able to transmit a result of the imaging operation to a processing device 102 by wired communication or to transmit the result to a processing device 103 by wireless communication. In addition, the semiconductor device 1 also has a function to perform a sensing operation to detect a position of a detection target 109, using a wireless signal. As illustrated in FIG. 2, the semiconductor device 1 has terminals T1 to T4. The terminal T1 of the semiconductor device 1 is coupled to a crystal oscillator 101. The semiconductor device 1 operates on a basis of a reference clock signal REFCLK supplied from the crystal oscillator 101. It is to be noted that this is not limitative, and the reference clock signal REFCLK may be supplied from any circuit. The terminal T2 is coupled to the processing device 102 via a transmission path 108. The semiconductor device 1 transmits a data signal DT to the processing device 102 by wired communication. The data signal DT may be a single-ended signal or a differential signal. The semiconductor device 1 performs wireless communication with the processing device 103, using an antenna AT1 coupled to the terminal T3 and an antenna AT2 coupled to the terminal T4. In addition, the semiconductor device 1 is adapted to perform a sensing operation to detect the position of the detection target 109, using the antenna AT1 coupled to the terminal T3 and the antenna AT2 coupled to the terminal T4. For example, the semiconductor device 1 is formed on one semiconductor chip or on a plurality of semiconductor chips that is laminated to each other.

The semiconductor device 1 (FIG. 1) includes a pixel array 11, an ADC (Analog to Digital Converter) 12, an imaging control circuit 13, a PLL (Phase Locked Loop) 14, a processing circuit 15, a PLL 20, a modulation circuit 30, a wired transmission circuit 40, a wireless control circuit 17, a wireless transmission circuit 50, a wireless reception circuit 60, and a processing circuit 18.

The pixel array 11 is configured to capture an image of a subject on the basis of an instruction from the imaging control circuit 13.

FIG. 3 illustrates a configuration example of the pixel array 11. The pixel array 11 includes a plurality of light-receiving pixels PIX that detects light. Each of the plurality of light-receiving pixels PIX generates a pixel signal corresponding to an amount of light received. The pixel array 11 is adapted to supply these pixel signals to the ADC 12.

The ADC 12 is configured to generate image data by performing an AD conversion operation on the basis of the plurality of pixel signals supplied from the pixel array 11. The ADC 12 operates on the basis of a clock signal CLK supplied from the PLL 14. The ADC 12 is adapted to supply the generated image data to the processing circuit 15 and the wired transmission circuit 40.

The imaging control circuit 13 is configured to control the operation of the pixel array 11 and the ADC 12. In addition, the imaging control circuit 13 also has a function to supply the wireless control circuit 17 with information regarding the timing of the imaging operation.

The PLL 14 is configured to generate the clock signal CLK having a frequency higher than a frequency of a reference clock signal REFCLK on the basis of the reference clock signal REFCLK supplied from the crystal oscillator 101. For example, it is possible for the PLL 14 to include what is called a digital PLL.

The processing circuit 15 is configured to perform predetermined processing on the image data supplied from the ADC 12 and supply the processed image data to the modulation circuit 33 (described later). For example, the processing circuit 15 includes a processor and memory and is adapted to operate on the basis of the clock signal CLK supplied from the PLL 14.

The PLL 20 is configured to generate an AC signal SIG having a frequency higher than the frequency of the reference clock signal REFCLK on the basis of the reference clock signal REFCLK supplied from the crystal oscillator 101. The PLL 20 generates the AC signal SIG on the basis of frequency data DF supplied from the modulation circuit 30. The frequency data DF is data indicating a frequency of the AC signal SIG.

FIG. 4 illustrates a configuration example of the PLL 20. For example, the PLL 20 is what is called a digital PLL. The PLL 20 includes a phase data generation circuit 21, a subtraction circuit 22, a loop filter 23, an addition circuit 24, an oscillation circuit 25, and a phase detection circuit 26. The phase data generation circuit 21, the loop filter 23, and the phase detection circuit 26 operate on the basis of the reference clock signal REFCLK.

The phase data generation circuit 21 is configured to generate phase data DP1 on the basis of the frequency data DF. Specifically, the phase data generation circuit 21 is adapted to calculate a phase value by cumulatively adding a frequency value indicated by the frequency data DF, and to generate the phase data DP1 indicating this phase value.

The subtraction circuit 22 is configured to generate phase error data ΔDP on the basis of the phase data DP1 and phase data DP2. Specifically, the subtraction circuit 22 is adapted to calculate a phase error value by subtracting the phase value indicated by the phase data DP2 from the phase value indicated by the phase data DP1, and to generate the phase error data ΔDP indicating this phase error value.

The loop filter 23 is configured to generate frequency control data DCTL1 by performing smoothing processing on the basis of the phase error data ΔDP. Specifically, the loop filter 23 is adapted to smooth the phase error value indicated by the phase error data ΔDP, and to generate the frequency control data DCTL1 indicating the smoothed phase error value.

The addition circuit 24 is configured to generate frequency control data DCTL2 on the basis of the frequency data DF and the frequency control data DCTL1. Specifically, the addition circuit 24 is adapted to add the value indicated by the frequency data DF and the value indicated by the frequency control data DCTL1, and to generate the frequency control data DCTL2 indicating a result of this addition.

Thus, the PLL 20 generates the frequency control data DCTL2 on the basis of the result of the addition of frequency control data DCTL1 generated on the basis of the frequency data DF and the frequency data DF. In addition, the PLL 20 supplies this frequency control data DCTL2 to the oscillation circuit 25. Even in a case where the frequency data DF changes in a short period of time, this allows the PLL 20 to vary the frequency of the AC signal SIG in accordance with a change in the frequency data DF.

The oscillation circuit 25 is configured to generate the AC signal SIG having a frequency corresponding to the frequency control data DCTL2 on the basis of the frequency control data DCTL2.

The phase detection circuit 26 is configured to detect the phase of the AC signal SIG, and to generate the phase data DP2 indicating a result of the detection. The phase detection circuit 26 includes a counter 27, a TDC (Time to Digital Converter) 28, and an addition circuit 29. The counter 27 is configured to obtain an integer portion of the phase value of the AC signal SIG by counting the number of pulses of the AC signal SIG. The TDC 28 is configured to obtain a decimal portion of the phase value of the AC signal SIG by comparing a transition timing of the AC signal SIG with a transition timing of the reference clock signal REFCLK. The addition circuit 29 is configured to calculate the phase value of the AC signal SIG by adding the integer portion of the phase value of the AC signal SIG obtained by the counter 27 and the decimal portion of the phase value of the AC signal SIG obtained by the TDC 28, and to generate the phase data DP2 indicating this phase value.

This configuration causes the PLL 20 to generate the AC signal SIG on the basis of the frequency data DF supplied from the modulation circuit 30. For example, the frequency data DF varies on a time axis. This allows the PLL 20 to generate the AC signal SIG that is modulated on the basis of this frequency data DF.

The modulation circuit 30 is configured to modulate the AC signal SIG by controlling an operation of the PLL 20. The modulation circuit 30 includes modulation circuits 31, 33, and 35 and switches 32, 34, and 36.

The modulation circuit 31 is configured to generate the frequency data DF in a case where the semiconductor device 1 performs wired communication. The switch 32 is configured to be turned on in a case where the semiconductor device 1 performs wired communication, thereby to supply the PLL 20 with the frequency data DF generated by the modulation circuit 31.

FIG. 5 illustrates one example of the frequency indicated by the frequency data DF generated by the modulation circuit 31. The frequency indicated by the frequency data DF generated by the modulation circuit 31 varies gradually with a lapse of time. In this example, as illustrated in FIG. 5, the frequency varies like a triangular wave. In a case where the semiconductor device 1 performs wired communication, the PLL 20 generates the AC signal SIG on the basis of such frequency data DF. Accordingly, the frequency of the AC signal SIG varies as illustrated in FIG. 5. The semiconductor device 1 generates the data signal DT by using this AC signal SIG as a clock signal. This makes it possible for the system including the semiconductor device 1 to reduce EMI (Electromagnetic interference).

The modulation circuit 33 is configured to generate the frequency data DF in a case where the semiconductor device 1 performs wireless communication. Specifically, for example, the modulation circuit 33 generates the frequency data DF corresponding to the image data supplied from the processing circuit 15, or the frequency data corresponding to the sensing data supplied from the processing circuit 18. The modulation circuit 33 is adapted to operate during a period in which the semiconductor device 1 performs wireless communication and to stop operating during another other period, on the basis of the wireless control signal CTL supplied from the wireless control circuit 17. In a case where the semiconductor device 1 performs wireless communication, the switch 34 is configured to turn on, thereby supplying the frequency data DF generated by the modulation circuit 33 to the PLL 20. In a case where the semiconductor device 1 performs wireless communication, the PLL 20 generates the AC signal SIG on the basis of such frequency data DF. In other words, the AC signal SIG is a signal having a phase modulated in accordance with the image data or the sensing data, or having a frequency modulated in accordance with the image data or sensing data. The semiconductor device 1 is adapted to transmit such an AC signal SIG as a wireless signal.

The modulation circuit 35 is configured to generate the frequency data DF in a case where the semiconductor device 1 performs the sensing operation. The modulation circuit 35 is adapted to operate during a period in which the semiconductor device 1 performs the sensing operation and to stop operating during another period, on the basis of the wireless control signal CTL supplied from the wireless control circuit 17. The switch 36 is configured to be turned on in the case where the semiconductor device 1 performs the sensing operation, to thereby supply the PLL 20 with the frequency data DF generated by the modulation circuit 35.

FIG. 6 illustrates one example of the frequency indicated by the frequency data DF generated by the modulation circuit 35. The frequency indicated by the frequency data DF generated by the modulation circuit 35 varies gradually with a lapse of time. In this example, as illustrated in FIG. 6, the frequency varies to cause the frequency to gradually increase in each of a plurality of intermittently set periods P. In the case where the semiconductor device 1 performs the sensing operation, the PLL 20 generates the AC signal SIG on the basis of such frequency data DF. Accordingly, the frequency of the AC signal SIG varies as illustrated in FIG. 6. In other words, the AC signal SIG is what is called a chirp signal. It is to be noted that in this example, the frequency is adapted to gradually increase during the period P, but this is not limitative, and the frequency may gradually decrease. The semiconductor device 1 is adapted to transmit such an AC signal SIG as a wireless signal.

The wired transmission circuit 40 is configured to transmit by wired communication, the image data generated by the ADC 12 and the sensing data generated by the processing circuit 18. The wired transmission circuit 40 includes a signal generation circuit 41 and a driver 42. The signal generation circuit 41 is configured to generate a data signal by using the AC signal SIG as a clock signal, on the basis of the image data generated by the ADC 12 and the sensing data generated by the processing circuit 18. The driver 42 is configured to transmit, as the data signal DT, the data signal generated by the signal generation circuit 41.

The wireless control circuit 17 is configured to control, using the wireless control signal CTL, the wireless communication operation and the sensing operation of the semiconductor device 1 by controlling the operations of the modulation circuits 33 and 35 and a power amplifier 51 (described later). The wireless control circuit 17 is adapted to control the wireless communication operation and the sensing operation of the semiconductor device 1 on the basis of information supplied from the imaging control circuit 13 regarding the timing of the imaging operation.

The wireless transmission circuit 50 is configured to transmit by wireless communication, the image data generated by the ADC 12 and the sensing data generated by the processing circuit 18. In addition, the wireless transmission circuit 50 also has a function to transmit a chirp signal when performing the sensing operation. The wireless transmission circuit 50 includes the power amplifier 51 and a matching circuit 52. The power amplifier 51 is configured to amplify the AC signal SIG. The power amplifier 51 is adapted to operate during a period in which a wireless signal is transmitted and a period in which the sensing operation is performed, and to stop operating during another period, on the basis of the wireless control signal CTL supplied from the wireless control circuit 17. The matching circuit 52 is inserted and coupled between the power amplifier 51 and the antenna AT1 and is configured to perform impedance matching.

The wireless reception circuit 60 is configured to receive data transmitted from a communication partner in wireless communication (for example, the processing device 103). In addition, the wireless reception circuit 60 also has a function to receive a wireless signal reflected by the detection target 109 when performing the sensing operation. The wireless reception circuit 60 includes a matching circuit 61, a LNA (Low Noise Amplifier) 62, a mixer 63, a filter 64, and an ADC 65. The matching circuit 61 is inserted and coupled between the antenna AT2 and the LNA 62 to perform impedance matching. The LNA 62 is configured to amplify the signal supplied from the antenna AT2. The mixer 63 is configured to perform mixing of the AC signal SIG and the signal supplied from the LNA 62. For example, the filter 64 is a low-pass filter and is configured to supply the ADC 65 with a low-frequency component included in the signal supplied from the mixer 63. The ADC 65 is configured to operate on the basis of the clock signal CLK, and to perform the AD conversion operation on the basis of the signal supplied from the filter 64.

The processing circuit 18 is configured to generate the sensing data by performing predetermined processing on the data supplied from the ADC 65 in the wireless reception circuit 60. Then, the processing circuit 18 supplies the generated sensing data to the modulation circuit 33 and the signal generation circuit 41. For example, the processing circuit 18 includes a processor and memory, and is adapted to operate on the basis of the clock signal CLK supplied from the PLL 14.

Here, the pixel array 11 corresponds to one specific example of a “light detector” in the present disclosure. The PLL 20 corresponds to one specific example of a “phase synchronizing circuit” in the present disclosure. The modulation circuit 30 corresponds to one specific example of a “modulation circuit” in the present disclosure. The wired transmission circuit 40 corresponds to one specific example of a “wired transmission circuit” in the present disclosure. The wireless transmission circuit 50 corresponds to one specific example of a “wireless transmission circuit” in the present disclosure. The wireless reception circuit 60 corresponds to one specific example of a “wireless reception circuit” in the present disclosure.

### Workings and Effects

Subsequently, workings and effects of the semiconductor device 1 according to the present embodiment will be described.

### Summary of Overall Operation

First, an overview of an overall operation of the semiconductor device 1 will be described with reference to FIG. 1. The pixel array 11 generates a pixel signal by capturing an image of a subject on the basis of an instruction from the imaging control circuit 13. The ADC 12 generates image data by performing the AD conversion operation on the basis of a plurality of pixel signals supplied from the pixel array 11. The imaging control circuit 13 controls the operation of the pixel array 11 and the ADC 12. In addition, the imaging control circuit 13 supplies the wireless control circuit 17 with information regarding the timing of the imaging operation. The PLL 14 generates the clock signal CLK on the basis of the reference clock signal REFCLK. The processing circuit 15 performs predetermined processing on the image data supplied from the ADC 12 and supplies the processed image data to the modulation circuit 33. The PLL 20 generates the AC signal SIG on the basis of the reference clock signal REFCLK. The modulation circuit 30 modulates the AC signal SIG by controlling the operation of the PLL 20. The wired transmission circuit 40 transmits by wired communication, the image data generated by the ADC 12 and the sensing data generated by the processing circuit 18. The wireless control circuit 17 controls the wireless communication operation or the sensing operation of the semiconductor device 1 by controlling the operation of the modulation circuits 33 and 35 and the power amplifier 51 using the wireless control signal CTL. The wireless transmission circuit 50 transmits by wireless communication, the image data generated by the ADC 12 and the sensing data generated by the processing circuit 18. In addition, the wireless transmission circuit 50 transmits a chirp signal when performing the sensing operation. The wireless reception circuit 60 receives the data transmitted from the communication partner in wireless communication. In addition, the wireless reception circuit 60 receives a wireless signal reflected by the detection target 109 when performing the sensing operation. The processing circuit 18 generates the sensing data by performing predetermined processing on the data supplied from the wireless reception circuit 60.

### (Detailed Operation)

Next, the wired communication operation, the wireless communication operation, and the sensing operation in the semiconductor device 1 will be described in detail.

### (Wired Communication Operation)

FIG. 7 illustrates one example of the wired communication operation of the semiconductor device 1. FIG. 7 illustrates a main signal flow in the wired communication operation, using a bold line.

In this example, the pixel array 11 generates a pixel signal by capturing an image of a subject on the basis of an instruction from the imaging control circuit 13. The ADC 12 generates image data by performing the AD conversion operation on the basis of a plurality of pixel signals supplied from the pixel array 11. As illustrated in FIG. 5, the modulation circuit 31 generates the frequency data DF having a frequency that varies like a triangular wave. The switch 32 is in an on state. The PLL 20 generates the AC signal SIG on the basis of the frequency data DF supplied from the modulation circuit 31 via the switch 32. As illustrated in FIG. 5, the frequency of the AC signal SIG varies. The signal generation circuit 41 in the wired transmission circuit 40 generates the data signal by using the AC signal SIG as a clock signal, on the basis of the image data generated by the ADC 12. The driver 42 transmits, as the data signal DT, the data signal generated by the signal generation circuit 41. Thus, the wired transmission circuit 40 transmits the data signal DT including image data to the processing device 102 (FIG. 2). Because the frequency of the AC signal SIG varies, a symbol rate of the data signal DT also varies likewise. This makes it possible for the system including the semiconductor device 1 to reduce EMI.

FIG. 8 illustrates another example of the wired communication operation of the semiconductor device 1. In this example, the semiconductor device 1 performs the sensing operation described later, and the processing circuit 18 generates the sensing data. As illustrated in FIG. 5, the modulation circuit 31 generates the frequency data DF indicating a frequency that varies like a triangular wave. The switch 32 is in an on state. The PLL 20 generates the AC signal SIG on the basis of the frequency data DF supplied from the modulation circuit 31 via the switch 32. The signal generation circuit 41 in the wired transmission circuit 40 generates the data signal by using the AC signal SIG as a clock signal, on the basis of the sensing data generated by the processing circuit 18. The driver 42 transmits, as the data signal DT, the data signal generated by the signal generation circuit 41. In this way, the wired transmission circuit 40 transmits the data signal DT including the sensing data to the processing device 102 (FIG. 2).

### (Wireless Communication Operation)

FIG. 9 illustrates one example of the wireless communication operation of the semiconductor device 1. FIG. 9 illustrates a main signal flow in the wireless communication operation, using a bold line.

In this example, the pixel array 11 generates a pixel signal by capturing an image of a subject on the basis of an instruction from the imaging control circuit 13. The ADC 12 generates image data by performing the AD conversion operation on the basis of a plurality of pixel signals supplied from the pixel array 11. The processing circuit 15 performs predetermined processing on the image data supplied from the ADC 12 and supplies the processed image data to the modulation circuit 33. The modulation circuit 33 generates the frequency data DF corresponding to the image data supplied from the processing circuit 15. The switch 34 is in an on state. The PLL 20 generates the AC signal SIG on the basis of the frequency data DF supplied from the modulation circuit 33 via the switch 34. In other words, the AC signal SIG is a signal having a phase modulated in accordance with the image data or having a frequency modulated in accordance with the image data. The power amplifier 51 in the wireless transmission circuit 50 amplifies this AC signal SIG. The antenna AT1 transmits a wireless signal. Thus, the wireless transmission circuit 50 transmits the wireless signal including the image data to the processing device 103 (FIG. 2).

FIG. 10 illustrates one example of a period in which wireless communication is performed during a frame period F of the imaging operation, with (A) illustrating a waveform of a synchronization signal Vsync, with (B) illustrating a waveform of a synchronization signal Hsync, with (C) illustrating output data of the ADC 12, and with (D) illustrating a waveform of the wireless control signal CTL.

At timing t11, the frame period F starts. The synchronization signal Vsync transitions from a high level to a low level at timing t11, and transitions from a low level to a high level at timing t12 (FIG. 10(A)). The synchronization signal Hsync transitions from a high level to a low level at a starting timing of each of a plurality of horizontal periods H in the frame period F, and transitions from a low level to a high level at a timing when a predetermined time has elapsed from the starting timing (FIG. 10(B)). In this example, the ADC 12 outputs data at a timing when the synchronization signal Hsync transitions from a high level to a low level (FIG. 10(C)). The ADC 12 outputs data relating to a region other than an effective pixel region during a period of timing t13 to t14, outputs data relating to the effective pixel region during a period of timing t14 to t15, and outputs data relating to a region other than the effective pixel region in a period of timing t15 to t16. In this example, the wireless control signal CTL transitions from a low level to a high level at timing t11, and transitions from a high level to a low level at timing t12 (FIG. 10(D)). In other words, in this example, the wireless control signal CTL becomes high level during the period in which the synchronization signal Vsync is at a low level.

During a period of timing t11 to t12 in which the wireless control signal CTL is at a high level, the modulation circuit 33 generates the frequency data DF corresponding to the image data supplied from the processing circuit 15, and the PLL 20 generates the AC signal SIG on the basis of this frequency data DF. During this period of timing t11 to t12, the power amplifier 51 transmits this AC signal SIG. Thus, the semiconductor device 1 transmits the AC signal SIG during the period in which the pixel array 11 does not perform the imaging operation.

The semiconductor device 1 is configured to exclusively perform the imaging operation and the wireless communication operation. For example, because the power amplifier 51 deals with a large amount of power, the operation of the power amplifier 51 is likely to affect an image quality of the captured image. In addition, the imaging operation is also likely to affect the wireless signal. For the semiconductor device 1, it is possible to exclusively perform the imaging operation and the wireless communication operation. As a result, it becomes possible for the semiconductor device 1 to suppress a deterioration in image quality of the captured image or reduce a possibility of the imaging operation affecting the wireless signal.

FIG. 11 illustrates another example of a period in which wireless communication is performed in the frame period F of the imaging operation. In this example, the wireless control signal CTL transitions from a low level to a high level at timing t11, and transitions from a high level to a low level at timing t14 when the ADC 12 starts outputting the data relating to the effective pixel region (FIG. 11(D)). In addition, the wireless control signal CTL transitions from a low level to a high level at timing t15 when the ADC 12 finishes outputting the data relating to the effective pixel region.

During the period of timing t11 to t14 and the period of timing t15 to t16 when the wireless control signal CTL is at a high level, the modulation circuit 33 generates the frequency data DF corresponding to the image data supplied from the processing circuit 15, and the PLL 20 generates the AC signal SIG on the basis of this frequency data DF. The power amplifier 51 transmits this AC signal SIG during the period of timing t11 to t14 and the period of timing t15 to t16. In this example, it is possible to secure time to perform wireless communication compared with the example in FIG. 10.

FIG. 12 illustrates another example of a period in which wireless communication is performed in the frame period F of the imaging operation. Furthermore, in this example, compared with the case of FIG. 11, the wireless control signal CTL is at a high level during a period in which the synchronization signal Hsync is at a low level during the period of timing t14 to t15 in which the ADC 12 outputs the data relating to the effective pixel region. In this example, compared with the example in FIG. 11, it is possible to further secure time to perform wireless communication.

In the semiconductor device 1, the imaging control circuit 13 supplies the wireless control circuit 17 with information regarding the timing of the imaging operation. Then, the wireless control circuit 17 controls the wireless communication operation of the semiconductor device 1 on the basis of the information supplied from the imaging control circuit 13 regarding the timing of the imaging operation. In the semiconductor device 1, for example, the imaging control circuit 13 and the wireless control circuit 17 are formed on a single semiconductor chip or on a plurality of semiconductor chips that are laminated to each other. This allows the semiconductor device 1 to suppress signal delay time between the imaging control circuit 13 and the wireless control circuit 17, thus making it possible for the semiconductor device 1 to switch operations between the imaging operation and the wireless communication operation in the frame period F as illustrated in FIGS. 10 to 12.

FIG. 13 illustrates another example of the wireless communication operation of the semiconductor device 1. In this example, the semiconductor device 1 performs the sensing operation described later, and the processing circuit 18 generates the sensing data. The modulation circuit 33 generates the frequency data DF corresponding to the sensing data supplied from the processing circuit 18. The switch 34 is in an on state. The PLL 20 generates the AC signal SIG on the basis of the frequency data DF supplied from the modulation circuit 33 via the switch 34. The power amplifier 51 in the wireless transmission circuit 50 amplifies this AC signal SIG. The antenna AT1 transmits the wireless signal. Thus, the wireless transmission circuit 50 transmits the wireless signal including the sensing data to the processing device 103 (FIG. 2).

### (Sensing Operation)

FIG. 14 illustrates an example of the sensing operation of the semiconductor device 1. FIG. 14 illustrates a main signal flow in the sensing operation, using a bold line.

In this example, as illustrated in FIG. 6, the modulation circuit 35 generates the frequency data DF having a frequency that gradually varies in each of a plurality of intermittently set periods P. The switch 36 is in an on state. The PLL 20 generates the AC signal SIG on the basis of the frequency data DF supplied from the modulation circuit 35 via the switch 36. In other words, the AC signal SIG is what is called a chirp signal. The power amplifier 51 in the wireless transmission circuit 50 amplifies this AC signal SIG. The antenna AT1 transmits a wireless signal.

The antenna AT2 receives the wireless signal reflected by the detection target 109. The LNA 62 in the wireless reception circuit 60 amplifies the signal supplied from the antenna AT2. The mixer 63 performs mixing of the AC signal SIG and the signal supplied from the LNA 62.

FIG. 15 illustrates one example of an operation of the mixer 63. In FIG. 15, a dashed line indicates the frequency of the AC signal SIG, and a solid line indicates the frequency of the signal S62 supplied from the LNA 62. The signal S62 is a signal based on the wireless signal reflected by the detection target 109, and therefore is a signal with delayed timing compared with the AC signal SIG. The mixer 63 performs mixing of the AC signal SIG and the signal supplied from the LNA 62. This causes the mixer 63 to output a signal having a frequency component corresponding to a frequency difference between these two signals.

The filter 64 supplies the ADC 65 with a low frequency component in the signal supplied from mixer 63. The ADC 65 operates on the basis of the clock signal CLK, to perform the AD conversion operation on the basis of the signal supplied from the filter 64. The processing circuit 18 generates the sensing data by performing predetermined processing on the basis of a result of the AD conversion, which is supplied from the ADC 65 in the wireless reception circuit 60.

As illustrated in FIG. 15, a frequency difference Δf between the two signals inputted to the mixer 63 in the period P corresponds to a timing difference Δt between the AC signal SIG and the signal S62. This timing difference Δt corresponds to a distance between the semiconductor device 1 and the detection target 109. The processing circuit 18 calculates the frequency difference Δf on the basis of the result of the AD conversion supplied from the ADC 65, to calculate the timing difference Δt on the basis of this frequency difference Δf. Then, the processing circuit 18 calculates a distance between the semiconductor device 1 and the detection target 109 on the basis of this timing difference Δt.

Thus, the semiconductor device 1 includes the pixel array 11 including a plurality of light-receiving pixels PIX that detects light, the PLL 20 that generates the AC signal SIG, the modulation circuit 30 that modulates the AC signal SIG by controlling the operation of the PLL 20, the wired transmission circuit 40 that transmits a result of the detection by the pixel array 11 by using the AC signal SIG as a clock signal, and the wireless transmission circuit 50 that transmits the AC signal SIG modulated by the modulation circuit 30. In other words, in the semiconductor device 1, the PLL 20 is adapted to generate both the clock signal that is used in wired communication and the AC signal that is transmitted in wireless communication. This allows the semiconductor device 1 to reduce a circuit size as compared with a case of separately providing the PLL for wired communication and the PLL for wireless communication, thus allowing for a smaller circuit area.

In addition, in the semiconductor device 1, the modulation circuit 30 is adapted to modulate the AC signal SIG by controlling the operation of the PLL 20 on the basis of the result of the detection by the pixel array 11, and the wireless transmission circuit 50 is adapted to transmit the AC signal SIG modulated by the modulation circuit 30. The wireless transmission circuit 50 is adapted to operate in a first period including one or a plurality of periods out of the frame period F, and to stop operating in a second period other than this first period out of the frame period F. This allows the semiconductor device 1 to exclusively perform, for example, the imaging operation and the wireless communication operation. For example, because the power amplifier 51 deals with a large amount of power, the operation of the power amplifier 51 is likely to affect an image quality of the captured image. In addition, the imaging operation is also likely to affect the wireless signal. For example, for the semiconductor device 1, it is possible to exclusively perform the imaging operation and the wireless communication operation. As a result, for example, it becomes possible for the semiconductor device 1 to suppress a deterioration in image quality of the captured image.

### Effects

As described above, in the present embodiment, there are provided a pixel array including a plurality of light-receiving pixels that detects light, a PLL that generates an AC signal, a modulation circuit that modulates the AC signal by controlling the operation of the PLL, a wired transmission circuit that transmits a result of the detection by the pixel array by using the AC signal as a clock signal, and a wireless transmission circuit that transmits the AC signal modulated by the modulation circuit, thus allowing for a smaller circuit area.

As described above, in the present embodiment, the modulation circuit is adapted to modulate the AC signal by controlling the operation of the PLL on the basis of a result of the detection by the pixel array, and the wireless transmission circuit is adapted to transmit the AC signal modulated by the modulation circuit. The wireless transmission circuit is adapted to operate in a first period including one or a plurality of periods out of the frame period, and to stop operating in a second period other than this first period out of the frame period. This makes it possible to suppress a reduction in image quality of the captured image, for example.

### Modification Example 1

In the above embodiment, the matching circuit 52 and the matching circuit 61 are provided inside the semiconductor device 1 but are not limited to this, and may be formed outside a semiconductor device 1A, for example, as with the semiconductor device 1A illustrated in FIG. 16. The semiconductor device 1A includes a wireless transmission circuit 50A and a wireless reception circuit 60A. The wireless transmission circuit 50A includes a power amplifier 51. The power amplifier 51 has an output terminal coupled to the matching circuit 52A via the terminal T3. The matching circuit 52A is inserted and coupled between the terminal T3 and the antenna AT1. The wireless reception circuit 60A includes the LNA 62, the mixer 63, the filter 64, and the ADC 65. The LNA 62 has an input terminal coupled to a matching circuit 61A via the terminal T4. The matching circuit 61A is inserted and coupled between the antenna AT2 and the terminal T4.

### Modification Example 2

In the above embodiment, the wireless transmission circuit 50 is coupled to the antenna AT1, but this is not limitative. Instead of this, as illustrated in FIG. 17, for example, a power amplifier 71 may be provided between the wireless transmission circuit 50 and the antenna AT1 outside the semiconductor device 1. This allows the semiconductor device 1 and the power amplifier 71 to increase an electric power for transmitting the wireless signal.

### Modification Example 3

In the above embodiment, the wired transmission circuit 40 is coupled to the terminal T2 while the wireless transmission circuit 50 is coupled to the terminal T3, but this is not limitative. In the following, a semiconductor device 1C according to the present modification example will be described in detail.

FIG. 18 illustrates a configuration example of the semiconductor device 1C according to the present modification example. The semiconductor device 1C includes a terminal T5 and a switch 72. The wired transmission circuit 40 is coupled to the terminal T5. The switch 72 is configured to be turned on, thereby coupling the wireless transmission circuit 50 to the terminal T5. This terminal T5 is coupled to switches 73 and 74 outside the semiconductor device 1C. The switch 73 is configured to be turned on, thereby coupling the terminal T5 to the antenna At1. The switch 74 is configured to be turned on, thereby coupling the terminal T5 to the transmission path 108 (FIG. 2). This makes it possible to reduce the number of terminals in the semiconductor device 1C.

FIG. 19 illustrates one example of an operation of the semiconductor device 1C. For example, the semiconductor device 1C is configured to perform a wired communication operation on the image data, the sensing operation, and the wired communication operation on the sensing data by time division.

FIG. 20 illustrates one example of the wired communication operation of image data in the semiconductor device 1C. The pixel array 11 generates a pixel signal by capturing an image of a subject on the basis of an instruction from the imaging control circuit 13. The ADC 12 generates image data by performing the AD conversion operation on the basis of a plurality of pixel signals supplied from the pixel array 11. As illustrated in FIG. 5, the modulation circuit 31 generates the frequency data DF having a frequency that varies like a triangular wave. The switch 32 is in an on state. The PLL 20 generates the AC signal SIG on the basis of the frequency data DF supplied from the modulation circuit 31 via the switch 32. The signal generation circuit 41 in the wired transmission circuit 40 generates a data signal by using the AC signal SIG as a clock signal, on the basis of the image data generated by the ADC 12. The driver 42 transmits, as the data signal DT, the data signal generated by the signal generation circuit 41. The switch 74 is in an on state, and the switches 72 and 73 are in an off state. Thus, the wired transmission circuit 40 transmits the data signal DT including the image data to the processing device 102 (FIG. 2).

FIG. 21 illustrates an example of the sensing operation in the semiconductor device 1C. The modulation circuit 35 generates the frequency data DF having a frequency that gradually varies in each of a plurality of intermittently set periods P as illustrated in FIG. 6. The switch 36 is in an on state. The PLL 20 generates the AC signal SIG on the basis of the frequency data DF supplied from the modulation circuit 35 via the switch 36. The power amplifier 51 in the wireless transmission circuit 50 amplifies this AC signal SIG. The switches 72 and 73 are in an on state, and the switch 74 is in an off state. The antenna AT1 transmits the wireless signal. The antenna AT2 receives the wireless signal reflected by the detection target 109. The LNA 62 in the wireless reception circuit 60 amplifies the signal supplied from the antenna AT2. The mixer 63 performs mixing of the AC signal SIG and the signal supplied from the LNA 62. The filter 64 supplies the ADC 65 with a low-frequency component in the signal supplied from the mixer 63. The ADC 65 operates on the basis of the clock signal CLK and performs the AD conversion operation on the basis of the signal supplied from the filter 64. The processing circuit 18 generates the sensing data by performing predetermined processing on the basis of the result of the AD conversion, which is supplied from the ADC 65 in the wireless reception circuit 60.

FIG. 22 illustrates one example of the wired communication operation of the sensing data in the semiconductor device 1C. As illustrated in FIG. 5, the modulation circuit 31 generates the frequency data DF indicating a frequency that varies like a triangular wave. The switch 32 is in an on state. The PLL 20 generates the AC signal SIG on the basis of the frequency data DF supplied from the modulation circuit 31 via the switch 32. The signal generation circuit 41 in the wired transmission circuit 40 generates a data signal by using the AC signal SIG as a clock signal, on the basis of the sensing data generated by the processing circuit 18. The driver 42 transmits, as the data signal DT, the data signal generated by the signal generation circuit 41. The switch 74 is in an on state, and the switches 72 and 73 are in an off state. Thus, the wired transmission circuit 40 transmits the data signal DT including the sensing data to the processing device 102 (FIG. 2).

In this example, for example, the semiconductor device 1C performs the wired communication operation on the image data, the sensing operation, and the wired communication operation on the sensing data by time division, but this is not limitative. For example, the semiconductor device 1C may perform the wireless communication operation on the image data instead of performing the wired communication operation on the image data, or may perform the wireless communication operation on the sensing data instead of performing the wired communication operation on the sensing data.

In addition, in this example, the switch 73 is coupled to the antenna AT1, but this is not limitative. For example, as illustrated in FIG. 23, a power amplifier 71 may be provided between the switch 73 and the antenna AT1. This allows the semiconductor device 1C and the power amplifier 71 to increase an electric power to transmit the wireless signal.

### Modification Example 4

In the above embodiment, the semiconductor device 1 performs the imaging operation, but this is not limitative. Instead of this, the semiconductor device may perform a ranging operation. In the following, the present modification example will be described in detail.

FIG. 24 illustrates a configuration example of a semiconductor device 1D according to the present modification example. FIG. 25 illustrates a configuration example of a system including the semiconductor device 1D. This system is configured to emit light while detecting reflected light from a ranging target and detect a period of time from when the light is emitted to when the reflected light is detected. As illustrated in FIG. 25, the system includes a control device 111D and a light emitting device 112D. The control device 111D is configured to control the ranging operation in the system. The light emitting device 112D is configured to emit light on the basis of an instruction from the control device 111D. The semiconductor device 1D includes a terminal T6. The terminal T6 is coupled to the control device 111D. The semiconductor device 1D is configured to receive from the control device 111D, a trigger signal indicating the timing of light emission.

The semiconductor device 1D includes a pixel array 11D, a TDC 12D, and a ranging control circuit 13D. The pixel array 11D includes a plurality of light-receiving pixels PIX that detects light. Each of the plurality of light-receiving pixels PIX is configured to generate a pulse indicating the timing of light detection. The TDC 12D is configured to generate the image data of a ranging image by measuring a period of time from the timing of light emission to the timing of detection in each of the plurality of light-receiving pixels. The ranging control circuit 13D is configured to control the operation of the pixel array 11D and the TDC 12D on the basis of a trigger signal indicating the timing of light emission, which is supplied from the control device 111D. In addition, the ranging control circuit 13D is also adapted to supply the wireless control circuit 17 with information regarding the timing of the ranging operation.

### Modification Example 5

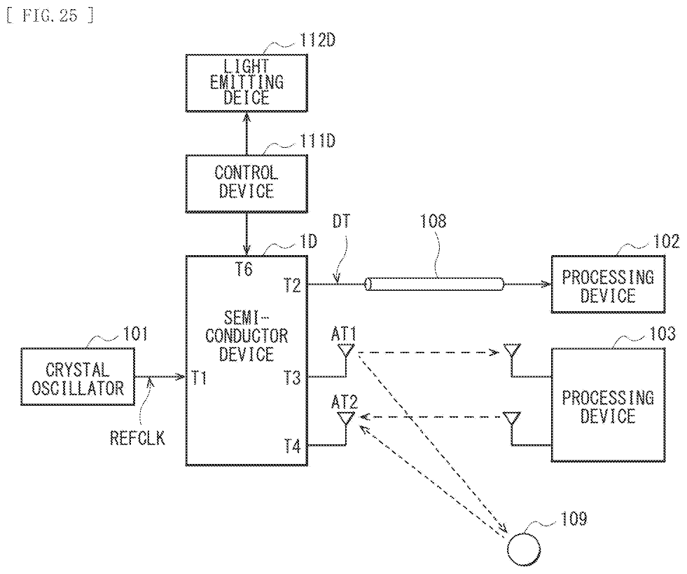

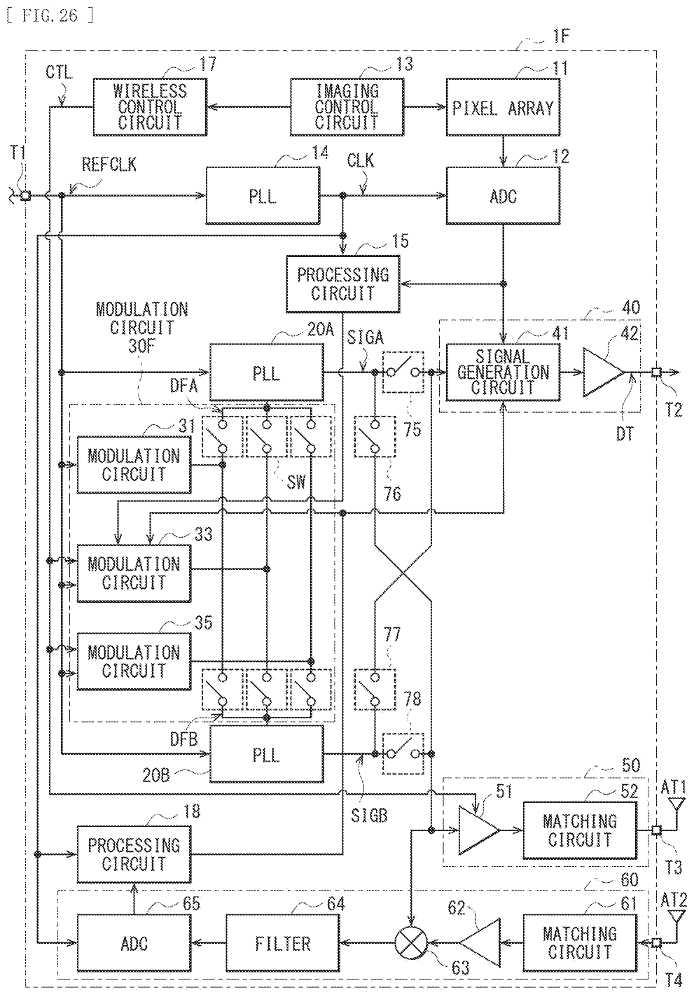

In the above embodiment, one PLL 20 is provided for use in the wired communication operation and the wireless communication operation, but this is not limitative. Instead of this, as illustrated in FIG. 26, for example, two PLLs having operating frequency ranges different from each other may be provided as in a semiconductor device 1F illustrated in FIG. 26. The semiconductor device 1F includes PLLs 20A and 20B, a modulation circuit 30F, and switches 75 to 77.

The PLL 20A is configured to generate the AC signal SIGA having a frequency higher than the frequency of the reference clock signal REFCLK on the basis of the reference clock signal REFCLK. The PLL 20A is adapted to generate the AC signal SIGA on the basis of the frequency data DFA supplied from the modulation circuit 30F. A PLL 20B is configured to generate the AC signal SIGB having a frequency higher than the frequency of the reference clock signal REFCLK on the basis of the reference clock signal REFCLK. The PLL 20B is adapted to generate the AC signal SIGB on the basis of the frequency data DFB supplied from the modulation circuit 30F. A range of the frequency of the AC signal SIGA that the PLL 20A is able to generate and a range of the frequency of the AC signal SIGB that the PLL 20B is able to generate are different from each other. Specifically, for example, the PLL 20A generates the AC signal SIGA having a frequency equal to or higher than 1 GHz and equal to or lower than 5 GHz, and the PLL 20B generates the AC signal SIGB having a frequency equal to or higher than 5 GHz and equal to or lower than 10 GHz. The PLLs 20A and 20B have the same circuit configuration as that of the PLL 20 (FIG. 4) according to the above embodiment.

The modulation circuit 30F is configured to modulate the AC signal SIGA by controlling the operation of the PLL 20A and to modulate the AC signal SIGB by controlling the operation of the PLL 20B. The modulation circuit 30F includes modulation circuits 31, 33, and 35, and six switches SW. The modulation circuit 30F is adapted to supply the PLL 20A with one of the frequency data generated by the modulation circuits 31, 33, and 35 as the frequency data DFA and to supply the PLL 20B with one of the frequency data generated by the modulation circuits 31, 33, and 35 as the frequency data DFB. For the modulation circuit 30F, for example, it is possible to supply the PLLs 20A and 20B with the frequency data DFA and DFB that are different from each other. Specifically, the modulation circuit 30F is adapted to be able to supply the PLL 20A with the frequency data generated by the modulation circuit 31 as the frequency data DFA, and to supply the PLL 20B with the frequency data generated by the modulation circuit 33 as the frequency data DFB.

The switch 75 is configured to be turned on, thereby supplying the AC signal SIGA to the wired transmission circuit 40. The switch 76 is configured to be turned on, thereby supplying the AC signal SIGA to the wireless transmission circuit 50 and the wireless reception circuit 60. The switch 77 is configured to be turned on, thereby supplying the AC signal SIGB to the wired transmission circuit 40. The switch 78 is configured to be turned on, thereby supplying the AC signal SIGB to the wireless transmission circuit 50 and the wireless reception circuit 60.

In the semiconductor device 1F, for example, in a case of turning on the switch 75 and turning off the switch 77, the AC signal SIGA generated by the PLL 20A is supplied to the wired transmission circuit 40. In addition, for example, in a case of turning on the switch 77 and turning off the switch 75, the AC signal SIGB generated by the PLL 20B is supplied to the wired transmission circuit 40. This allows the semiconductor device 1F to perform the wired communication operation on the basis of the AC signal across a wide frequency range.

Similarly, in the semiconductor device 1F, for example, in a case of turning on the switch 76 and turning off the switch 78, the AC signal SIGA generated by the PLL 20A is supplied to the wireless transmission circuit 50 and the wireless reception circuit 60. In addition, for example, in a case of turning on the switch 78 and turning off the switch 76, the AC signal SIGB generated by the PLL 20B is supplied to the wireless transmission circuit 50 and the wireless reception circuit 60. This allows the semiconductor device 1F to perform the wireless communication operation and the sensing operation on the basis of the AC signal across a wide frequency range. For example, this makes it possible to perform wireless communication across a wide frequency range, and it is also possible to be compatible with various wireless standards.

In addition, for example, the wired transmission circuit 40 is configured to operate on the basis of one of the AC signals SIGA and SIGB generated by the PLLs 20A and 20B, and the wireless transmission circuit 50 and the wireless reception circuit 60 are able to operate on the basis of another of the AC signals SIGA and SIGB. In this case, the semiconductor device 1F is able to perform wired and wireless communication operations simultaneously. The PLL 20A and the PLL 20B operate in frequency ranges different from each other, thus making it possible to reduce a possibility of causing the operations to interfere with each other, and as a result, to reduce a possibility of causing an operation failure.

In the semiconductor device 1F, for example, as compared with the case of providing two PLLs for wired communication and two PLLs for wireless communication, it is possible to reduce the circuit size, thus allowing for a smaller circuit area.

### Modification Example 6

In the above embodiment, the wireless transmission circuit 50 includes a single circuit and the wireless reception circuit 60 includes a single circuit, but this is not limitative. Instead of this, for example, a plurality of circuits may be included as in a semiconductor device 1G illustrated in FIG. 27.

The semiconductor device 1G includes a wireless transmission circuit 50G, a wireless reception circuit 60G, and a processing circuit 18G. The wireless transmission circuit 50G includes a plurality of circuits (in this example, three circuits). The wireless reception circuit 60G includes a plurality of circuits (in this example, three circuits). The processing circuit 18G is configured to generate the sensing data by performing predetermined processing on the data supplied from a plurality of (in this example, three) ADCs 65 in the wireless reception circuit 60G. For example, this configuration allows the semiconductor device 1G to realize what is called beamforming. Beamforming is usable, for example, in the wireless communication operation or the sensing operation. As a result, for example, it is possible for the semiconductor device 1G to increase radio interference immunity and increase sensitivity.

### Modification Example 7

In the above embodiment, the wireless transmission circuit 50 transmits a wireless signal having a modulated phase or frequency, but this is not limitative. Instead of this, for example, as with a semiconductor device 1H illustrated in FIG. 28, a wireless signal further having an amplitude modulated in addition to the phase and frequency may be transmitted. The semiconductor device 1H includes a modulation circuit 30H and a wireless transmission circuit 50H. The modulation circuit 30H includes a modulation circuit 33H. As with the modulation circuit 33 in the above embodiment, the modulation circuit 33H generates, for example, the frequency data DF corresponding to the image data supplied from the processing circuit 15 or the frequency data DF corresponding to the sensing data supplied from the processing circuit 18. In addition, for example, the modulation circuit 33H is adapted to control the operation of the power amplifier 51H (described later) in the wireless transmission circuit 50H on the basis of the image data supplied from the processing circuit 15, or to control the operation of the power amplifier 51H in accordance with the sensing data supplied from the processing circuit 18. The wireless transmission circuit 50H includes the power amplifier 51H. The power amplifier 51H includes a plurality of power amplifiers and is configured to be able to vary the amplitude of the wireless signal by changing, on the basis of an instruction from the modulation circuit 33H, the number of power amplifiers that operate simultaneously. This method is also called a digital polarization method. This allows the semiconductor device 1H to modulate the phase, frequency, and amplitude of the wireless signal. As a result, for example, it becomes possible for the semiconductor device 1H to increase the amount of data transmitted.

### Modification Example 8

In the above embodiment, the semiconductor device 1 includes the matching circuits 52 and 61 as illustrated in FIG. 1. As illustrated below, these matching circuits 52 and 61 allow for various circuit configurations.

FIG. 29 illustrates an example of the matching circuit 52 in the wireless transmission circuit 50. The matching circuit 52 includes a capacitor 54 and an inductor 55. The capacitor 54 has one end coupled to the power amplifier 51 while having another end coupled to one end of the inductor 55 and the terminal T3. The inductor 55 has one end coupled to another end of the capacitor 54 and the terminal T3 while having another end grounded. In this example, the matching circuit 52 is included in a high-pass filter.

FIG. 30 illustrates an example of the matching circuit 61 in the wireless reception circuit 60. The matching circuit 61 includes a transformer 67. The transformer 67 includes coils 67A and 67B. The coil 67A has one end coupled to a first input terminal of the LNA 62 and the terminal T4 while having another end grounded. The coil 67B has one end coupled to a second input terminal of the LNA 62 while having another end grounded.

FIG. 31 illustrates an implementation example of the capacitor 54 and the inductor 55 illustrated in FIG. 29 and the transformer 67 illustrated in FIG. 30. In this example, the semiconductor device 1 is formed on two semiconductor chips 100A and 100B that are laminated to each other. In this example, the pixel array 11 is formed on the semiconductor chip 100A, and the ADC 12, the imaging control circuit 13, the PLL 14, the processing circuit 15, the PLL 20, the modulation circuit 30, the wired transmission circuit 40, the wireless control circuit 17, and the processing circuit 18 are formed on the semiconductor chip 100B. In this example, the capacitor 54 and the inductor 55 in the wireless transmission circuit 50 are formed on the semiconductor chip 100A, and the power amplifier 51 is formed on the semiconductor chip 100B. In addition, the transformer 67 of the wireless reception circuit 60 is formed on the semiconductor chip 100A, and the LNA 62, the mixer 63, the filter 64, and the ADC 65 are formed on the semiconductor chip 100B. Thus, it is possible to reduce a chip size of the semiconductor chip 100B by disposing a capacitor, an inductor, a transformer, and the like in a free region in the semiconductor chip 100A.

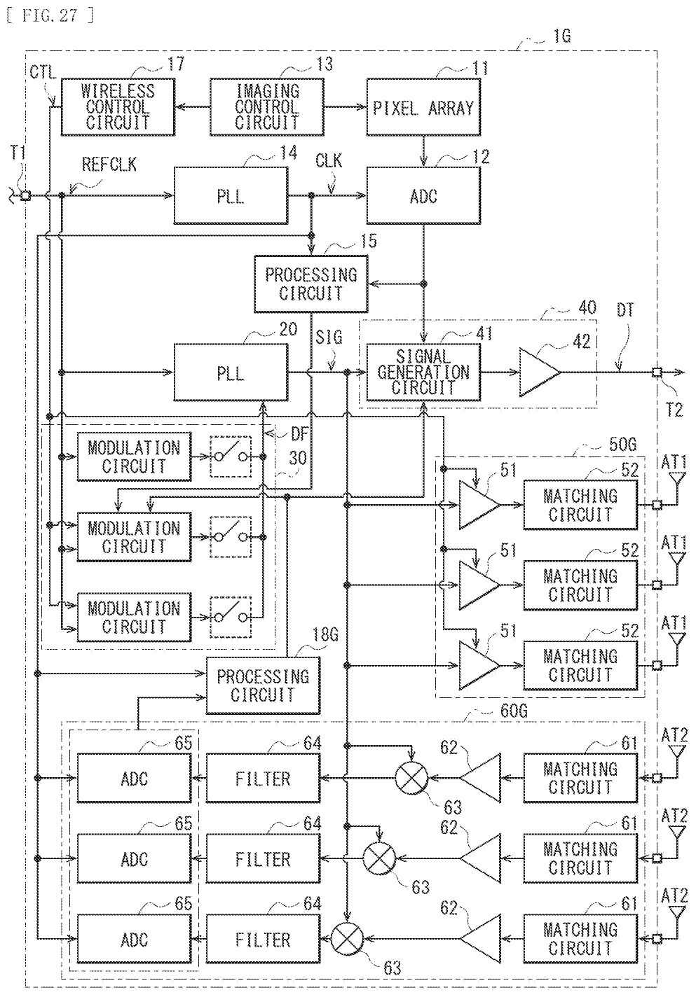

FIG. 32 illustrates a configuration example of the semiconductor chips 100A and 100B. The semiconductor chip 100A and the semiconductor chip 100B are joined at a bonding surface 190.

The semiconductor chip 100A includes a semiconductor substrate 120, a wiring layer 130, and an interlayer insulating layer 140. The semiconductor substrate 120 includes a light-receiving pixel 121. The wiring layer 130 includes a via 131, wirings 132 and 133, vias 134 and 135, and wirings 136 and 137. The wirings 132 and 133 are first metal layer wiring, and the wirings 136 and 137 are second metal layer wiring. The interlayer insulation layer 140 includes vias 141 and 142 and pads 143 and 144. The pads 143 and 144 face the bonding surface 190 and includes copper (Cu), for example.

The light-receiving pixel 121 is coupled to the wiring 132 through the via 131. The wiring 132 is coupled to the wiring 136 through the via 134. The wiring 136 is coupled to the pad 143 through the via 141.

The wirings 133 and 137 are included in the inductor 55 (FIG. 31). The wiring 133 is coupled to the wiring 137 through a plurality of vias 135. Thus, in this example, the inductor 55 includes the wiring 133 in the first metal layer and the wiring 137 in the second metal layer. This makes it possible to reduce the resistance value of the inductor 55, thus allowing for a higher Q-value. The wiring 137 is coupled to the pad 144 through the via 142.

The semiconductor chip 100B includes a semiconductor substrate 150, a wiring layer 160, and an interlayer insulating layer 170. In the semiconductor substrate 150, an element 151 is provided. The wiring layer 160 includes an element 161, a decoupling capacitor 162, vias 163 and 164, and wirings 166 and 167. The interlayer insulation layer 170 includes vias 171 and 172 and pads 173 and 174. The pads 173 and 174 face the bonding surface 190 and includes copper (Cu), for example.

The element 161 is coupled to the wiring 165 through the via 163. The wiring 165 is coupled to the pad 173 through the via 171. The pad 173 of the semiconductor chip 100B is coupled to the pad 143 of the semiconductor chip 100A by Cu—Cu bonding in this example.

The decoupling capacitor 162 is coupled to the wiring 166 through the via 164. The wiring 166 is coupled to the pad 174 through the via 172. The pad 174 of the semiconductor chip 100B is coupled to the pad 144 of the semiconductor chip 100A by Cu—Cu bonding in this example.

In this example, in the semiconductor chip 100A, the inductor 55 includes the wiring 133 of the first metal layer and the wiring 137 of the second metal layer, but this is not limitative. The inductor 55 may include the wiring of three or more metal layers, or the wiring of one metal layer.

In addition, although the example of the inductor has been described in FIG. 32, it is also possible to configure the capacitor 54, for example, using the first metal layer wiring and the second metal layer wiring.

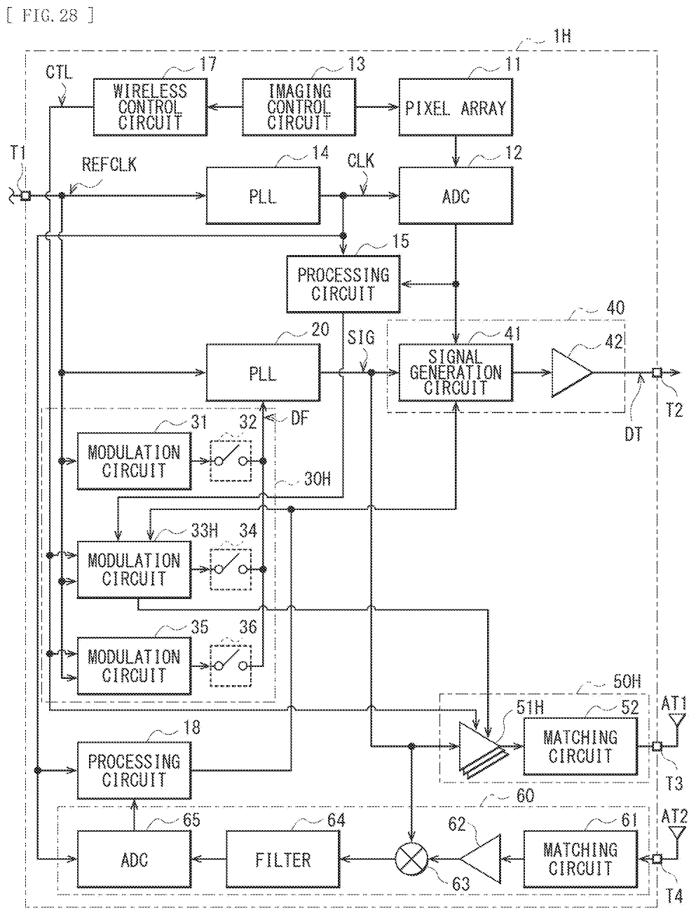

FIG. 33 illustrates another example of the matching circuit 52 in the wireless transmission circuit 50. The matching circuit 52 includes an inductor 56 and a capacitor 57. The inductor 56 has one end coupled to the power amplifier 51 while having another end coupled to one end of the capacitor 57 and the terminal T3. The capacitor 57 has one end coupled to another end of the inductor 56 and the terminal T3 while having another end grounded. In this example, the matching circuit 52 is included in a low-pass filter.

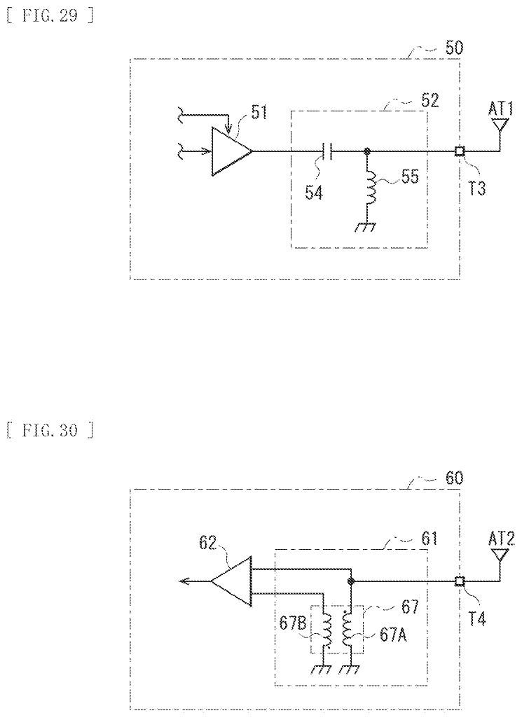

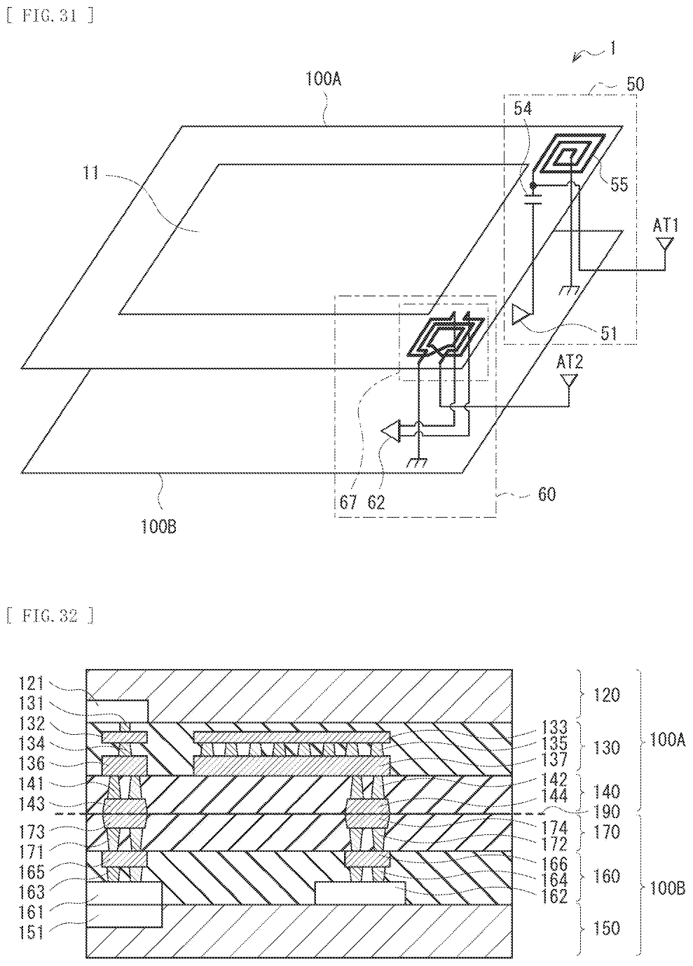

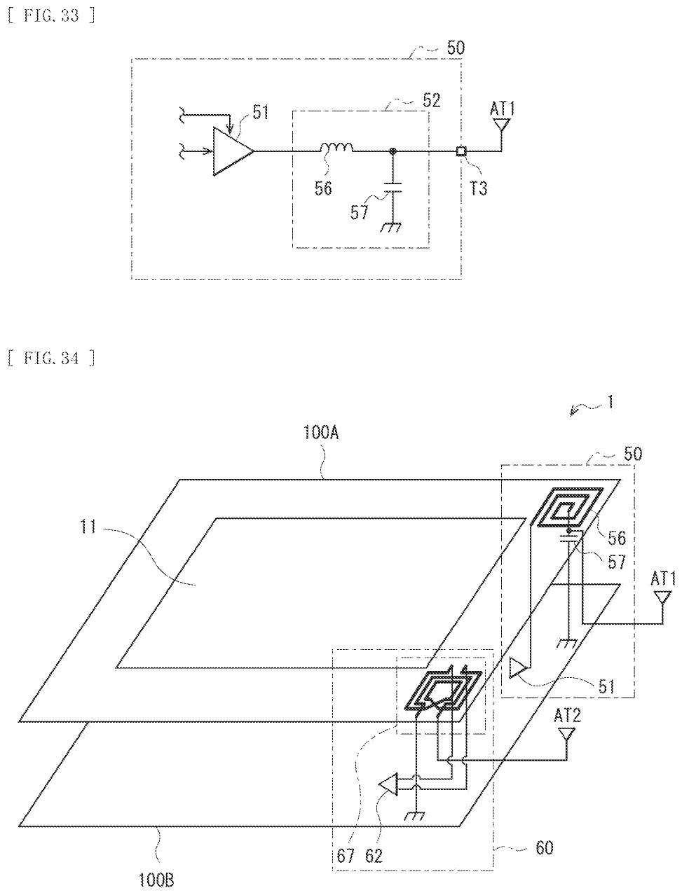

FIG. 34 illustrates an implementation example of the inductor 56 and the capacitor 57 illustrated in FIG. 33. It is to be noted that FIG. 34 also illustrates the transformer 67 illustrated in FIG. 30. In this example, the inductor 56 and the capacitor 57 in the wireless transmission circuit 50 are formed on the semiconductor chip 100A, and the power amplifier 51 is formed on the semiconductor chip 100B.

FIG. 35 illustrates another example of the matching circuit 52 in the wireless transmission circuit 50. The matching circuit 52 includes a transformer 58. The transformer 58 includes coils 58A and 58B. The coil 58A has one end coupled to the power amplifier 51 while having another end grounded. The coil 58B has one end coupled to the terminal T3 while having another end grounded.

FIG. 36 illustrates an implementation example of the transformer 58 illustrated in FIG. 35. It is to be noted that FIG. 36 also illustrates the transformer 67 illustrated in FIG. 30. In this example, the transformer 58 in the wireless transmission circuit 50 is formed on the semiconductor chip 100A, and the power amplifier 51 is formed on the semiconductor chip 100B.

### Modification Example 9

For the oscillation circuit 25 in the PLL 20 as illustrated in FIG. 4, it is possible to use an LC resonance-type oscillation circuit. As illustrated below, this oscillation circuit 25 allows for various circuit configurations.

FIG. 37 illustrates a configuration example of the oscillation circuit 25. The oscillation circuit 25 includes inductors 81 and 82, a varactor 83, transistors 84 and 85, and a current source 86. The transistors 84 and 85 are each an N-type MOS (Metal Oxide Semiconductor) transistor. The inductor 81 has one end supplied with a power supply voltage VDD while having another end coupled to one end of the varactor 83, to a drain of the transistor 84, and to a gate of the transistor 85. The inductor 82 has one end supplied with the supply voltage VDD while having another end coupled to another end of the varactor 83, to a drain of the transistor 85, and to a gate of the transistor 84. The varactor 83 is configured to cause a capacitance value between both ends to vary on the basis of the frequency control data DCTL2 (FIG. 4). The varactor 83 has one end coupled to another end of the inductor 81, to a drain of the transistor 84, and to a gate of the transistor 85 while having another end coupled to another end of the inductor 82, to a drain of the transistor 85, and to a gate of the transistor 84. The transistor 84 has a drain coupled to another end of the inductor 81, to one end of the varactor 83, and to a gate of the transistor 85, while having a gate coupled to another end of the inductor 82, to another end of the varactor 83, and to a drain of the transistor 85. The transistor 84 has a source coupled to a source of the transistor 85 and a current source 86. The transistor 85 has a drain coupled to another end of the inductor 82, to another end of the varactor 83, and to a gate of the transistor 84, while having a gate coupled to another end of the inductor 81, to one end of the varactor 83, and to a drain of the transistor 84, and having a source coupled to a source of the transistor 84 and the current source 86. The current source 86 has one end coupled to the sources of the transistors 84 and 85 while having another end grounded.

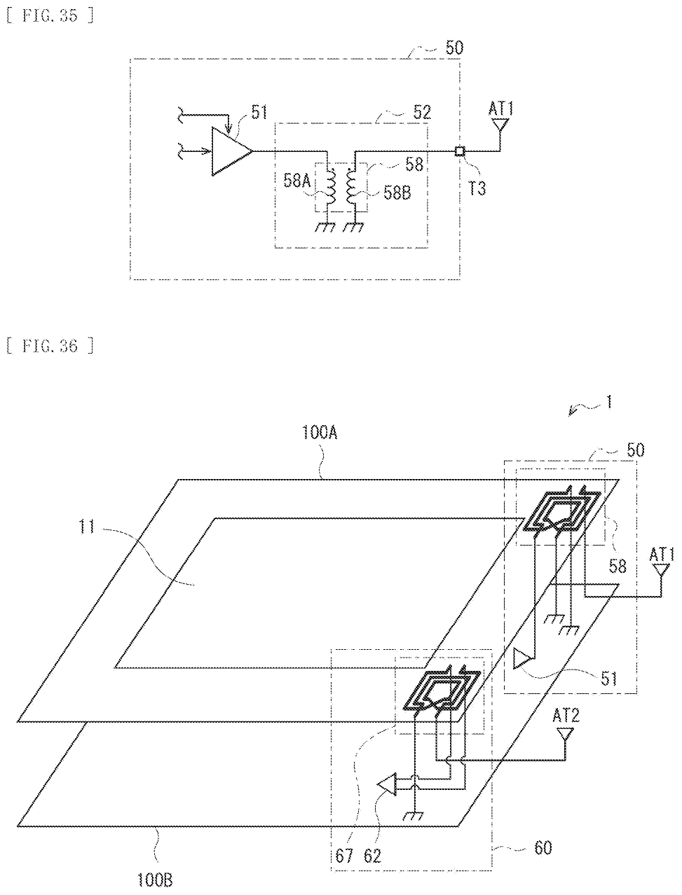

FIG. 38 illustrates an implementation example of the inductors 81 and 82 illustrated in FIG. 37. In this example, the inductors 81 and 82 are formed on the semiconductor chip 100A.

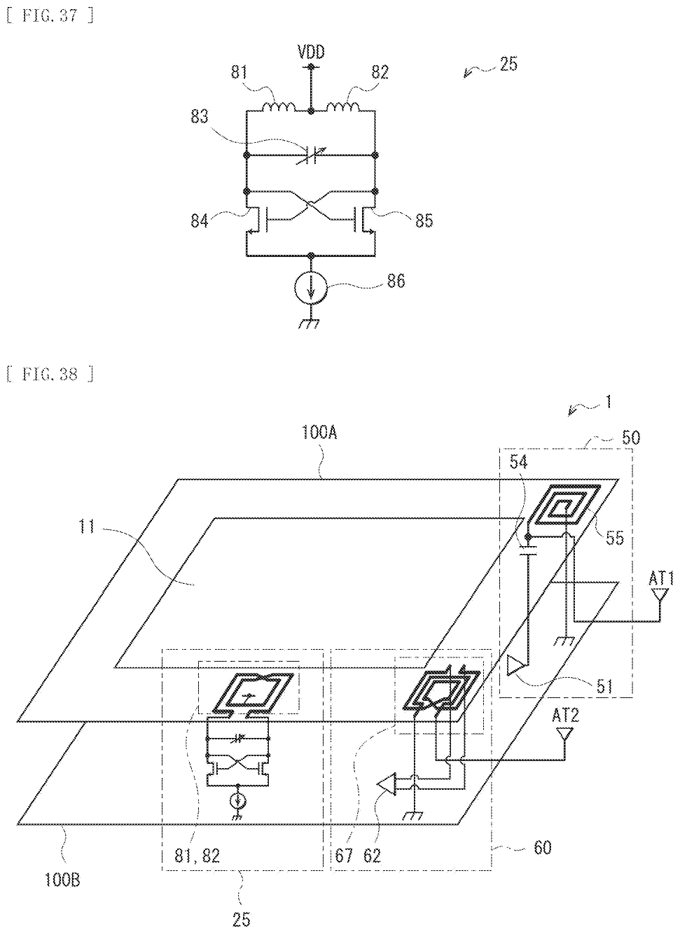

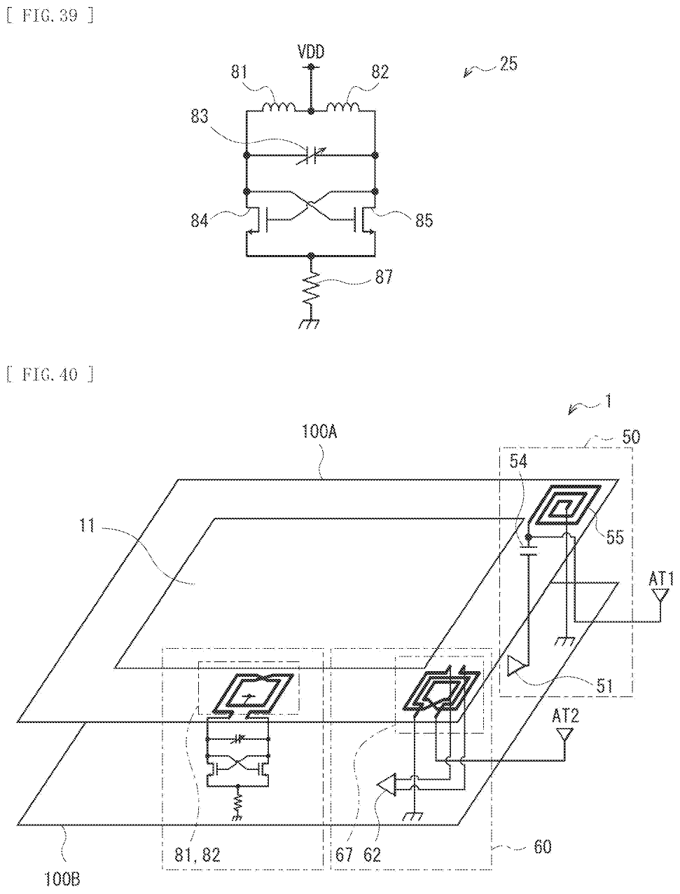

FIG. 39 illustrates another example of the oscillation circuit 25. FIG. 40 illustrates an implementation example of the inductors 81 and 82 illustrated in FIG. 39. The oscillation circuit 25 includes a resistance element 87. The resistance element 87 has one end coupled to a source of each of the transistors 84 and 85 while having another end grounded. The inductors 81 and 82 are formed on the semiconductor chip 100A.

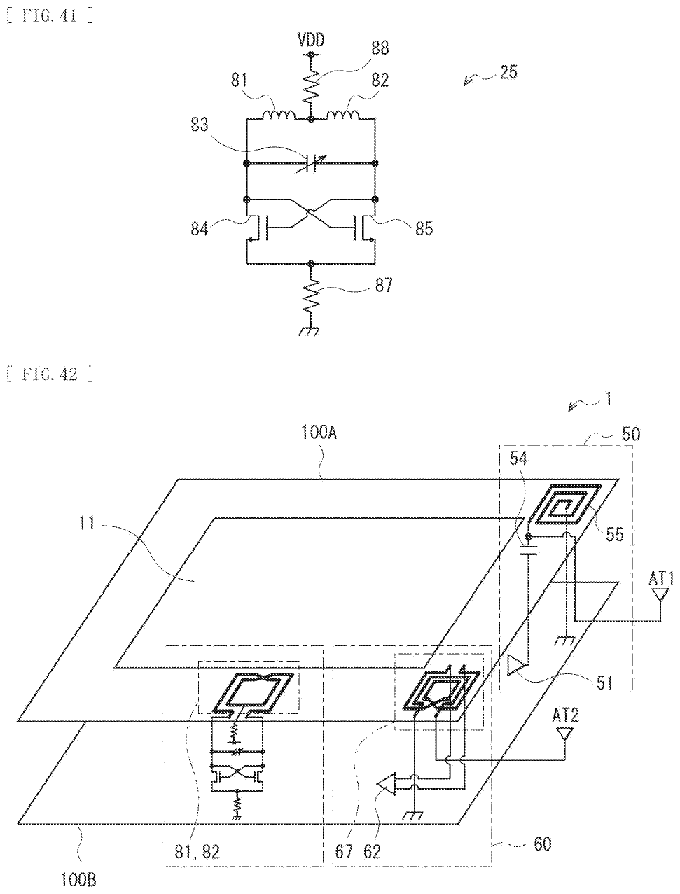

FIG. 41 illustrates another example of a configuration of the oscillation circuit 25. FIG. 42 illustrates an implementation example of the inductors 81 and 82 illustrated in FIG. 41. The oscillation circuit 25 includes a resistance element 88. The resistance element 88 has one end supplied with the power supply voltage VDD while having another end coupled to one end of the inductors 81 and 82. The inductors 81 and 82 are formed on the semiconductor chip 100A.

### Modification Example 10

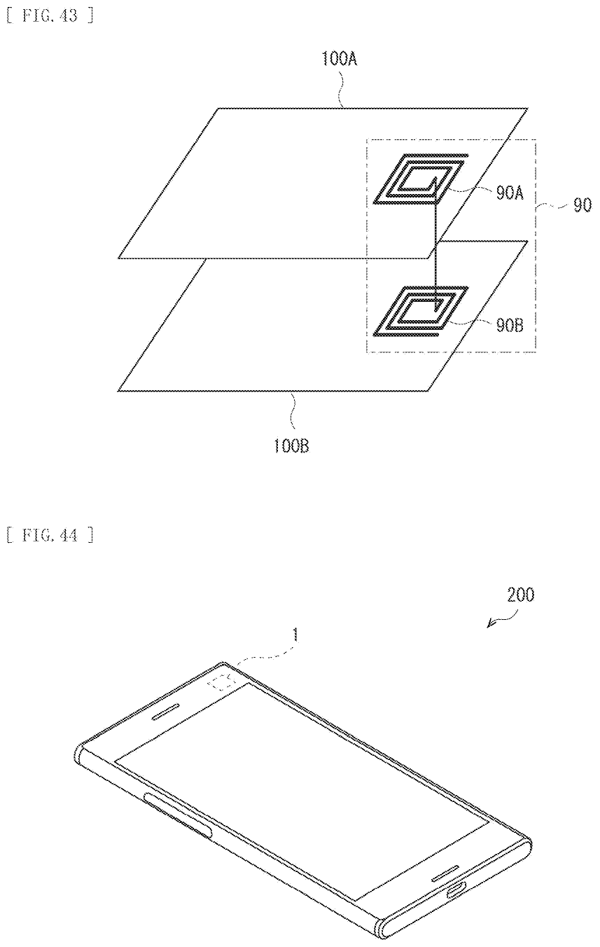

In Modification Examples 8 and 9, the inductor is provided on the semiconductor chip 100A, but this is not limitative. Instead of this, as with the inductor 90 illustrated in FIG. 43, for example, the inductor may be formed on both semiconductor chips 100A and 100B. The inductor 90 includes a coil 90A and a coil 90B. The coil 90A is formed in the semiconductor chip 100A, and the coil 90B is formed in the semiconductor chip 100B. For example, as illustrated in FIG. 32, an end of the coil 90A and an end of the coil 90B are coupled by Cu—Cu bonding. In a case where an electric current flows in this inductor 90, a magnetic flux generated at a center of the coil 90A by the coil 90A and a magnetic flux generated at a center of coil 90B by the coil 90B have the same direction. This magnetically couples the coils 90A and 90B. As a result, it is possible to increase the inductance in the inductor 90, thus allowing for a higher Q-value.

In this example, the coil 90A in the semiconductor chip 100A and the coil 90B in the semiconductor chip 100B are coupled in series. However, instead of this, for example, the coil 90A and the coil 90B may be coupled to each other by Cu—Cu bonding at various locations, as with the wirings 133 and 137 in the example of FIG. 32. In this case, it is possible to reduce a resistance value of the inductor, thus allowing for a higher Q-value.

### Other Modification Example

Two or more of these modification examples may be combined.

### 2. Application Example

Next, application examples of the semiconductor device 1 described in the above embodiment and modification examples will be described.

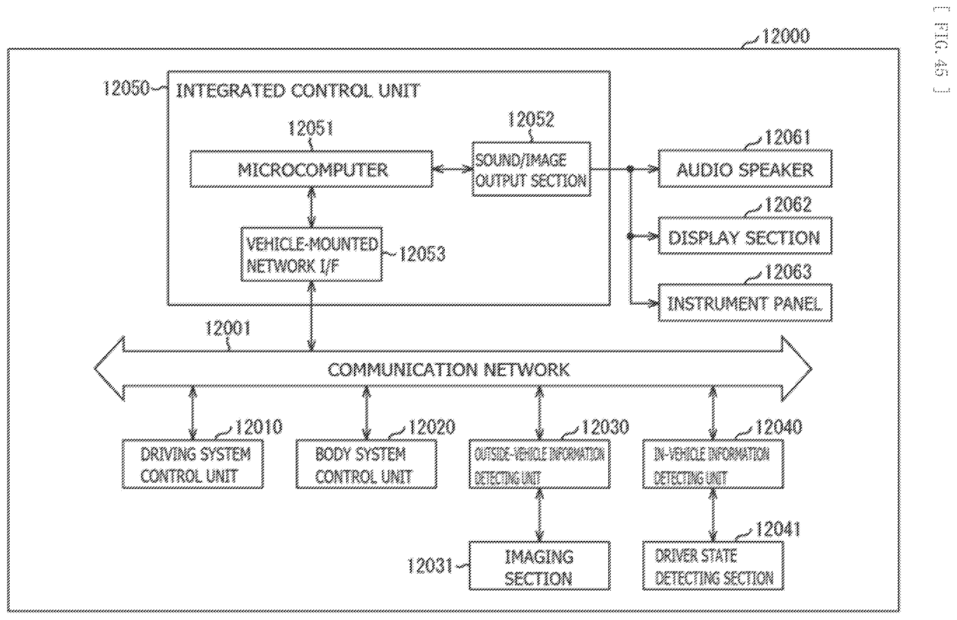

FIG. 44 illustrates an external view of a smartphone 200 to which the semiconductor device 1 of the above embodiment, etc. is applied. The smartphone 200 is incorporated with the semiconductor device 1. For example, the smartphone 200 is configured to generate image data by capturing an image of a subject and transmit the image data to a server by wireless communication. In addition, it is possible for the smartphone 200 to measure a distance to a nearby object by performing the sensing operations.

The semiconductor device 1 according to the above embodiment, etc. is applicable to various electronic apparatuses performing wireless communication other than a smart phone like this, such as a tablet terminal or the like.

### 3. Practical Application to Mobile Body

The technique of the present disclosure (the present technology) is applicable to various products. For example, the technique of the present disclosure may be realized as a device mounted on any type of mobile body, such as a car, electric vehicle, hybrid electric vehicle, motorcycle, bicycle, personal mobility vehicle, airplane, drone, ship, robot, or the like.

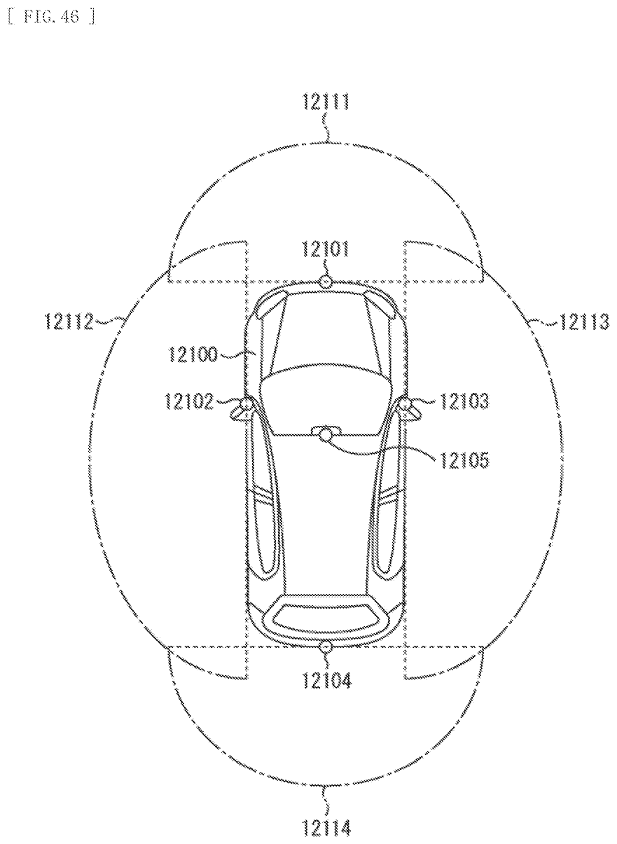

FIG. 45 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 45, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 45, an audio speaker 12061, a display section 12062, and an instrument panel 12063 are illustrated as the output device. The display section 12062 may, for example, include at least one of an on-board display and a head-up display.

FIG. 46 is a diagram depicting an example of the installation position of the imaging section 12031.

In FIG. 46, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 46 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

One example of a vehicle control system to which the technique of the present disclosure is applicable has been described above. The technique of the present disclosure is applicable to the imaging section 12031 of the above described configuration. For example, the vehicle control system 1200 is configured to transmit image data to a server via wireless communication. For example, for the vehicle control system 12000, it is possible to reduce circuit area, thus making it possible to reduce the size of the vehicle control system 12000 In addition, for example, for the vehicle control system 1200, it is possible to reduce a possibility of wireless communication affecting the quality of the captured image. Accordingly, even in a case of performing wireless communication in this manner, for the vehicle control system 1200, it is possible to realize a collision avoidance or collision mitigation function, a follow-up drive function on the basis of a vehicle distance, a vehicle speed maintenance function, a collision warning function for a vehicle, a lane departure warning function for a vehicle, or the like with high accuracy.

Although the technology has been described above referring to some embodiments and modification examples as well as specific application examples thereof, the technology is not limited to these embodiments, etc., and may be modified in a variety of ways.

For example, in each of the above embodiments, the semiconductor device 1 is formed on two semiconductor chips 100A and 100B, but this is not limitative. Instead of this, for example, the semiconductor device 1 may be formed on one semiconductor chip, or may be formed on three or more semiconductor chips.

It is to be noted that effects described herein are merely illustrative and are not limitative, and may have other effects.

It is to be noted that the present technique may have the following configurations. According to the present technique having the following configuration, it is possible to reduce circuit area.

(1)

A semiconductor device, including:
a light detector including a plurality of light-receiving pixels configured to detect light;
a phase synchronizing circuit configured to generate an AC signal;
a modulation circuit configured to modulate the AC signal by controlling an operation of the phase synchronizing circuit;
a wired transmission circuit configured to transmit a result of the detection by the light detector by using the AC signal as a clock signal; and
a wireless transmission circuit configured to transmit the AC signal modulated by the modulation circuit.
   (2)

The semiconductor device according to (1), in which
the light detector is configured to repeatedly perform a light detection operation on a basis of a frame period as a unit,
the modulation circuit is configured to modulate the AC signal by controlling the operation of the phase synchronizing circuit on a basis of the result of the detection by the light detector, and
the wireless transmission circuit is
configured to transmit the AC signal modulated by the modulation circuit, and
configured to operate during a first period and configured to stop operating during a second period, the first period including one or a plurality of periods out of the frame period, and the second period being out of the frame period and other than the first period.
   (3)

The semiconductor device according to (2), in which
the first period includes a period in which the light detection operation is not performed.
   (4)

The semiconductor device according to (2) or (3), further including a plurality of output terminals, in which
the wireless transmission circuit includes a plurality of transmission circuits led to the respective plurality of output terminals.
   (5)

The semiconductor device according to (1), further including a wireless reception circuit, in which
the modulation circuit is configured to modulate the AC signal, the modulation circuit modulating the AC signal by controlling the operation of the phase synchronizing circuit on a basis of a first predetermined signal,
the wireless transmission circuit is configured to transmit the AC signal modulated by the modulation circuit, and
the wireless reception circuit is configured to receive a signal that is based on the AC signal transmitted by the wireless transmission circuit.
   (6)

The semiconductor device according to (5), further including:
a plurality of output terminals; and
a plurality of input terminals, wherein
the wireless transmission circuit includes a plurality of reception circuits led to the respective plurality of output terminals, and
the wireless reception circuit includes a plurality of reception circuits led to the respective plurality of input terminals.
   (7)

The semiconductor device according to (1), in which
the wireless transmission circuit is configured to change an amplitude of the AC signal to be transmitted, and
the modulation circuit is further configured to modulate an amplitude of an output signal of the wireless transmission circuit by controlling an operation of the wireless transmission circuit.
   (8)

The semiconductor device according to (1), in which
the modulation circuit is configured to modulate the AC signal, the modulation circuit modulating the AC signal by controlling the operation of the phase synchronizing circuit on a basis of a second predetermined signal, and
the wired transmission circuit is configured to transmit the result of the detection by the light detector by using the AC signal as the clock signal, the AC signal being modulated by the modulation circuit.
   (9) The semiconductor device according to any one of (1) to (8), further including an output terminal led to the wired transmission circuit and to the wireless transmission circuit, wherein
the wired transmission circuit and the wireless transmission circuit are configured to operate exclusively.
   (10)

The semiconductor device according to any one of (1) to (8), in which
the AC signal includes a first AC signal and a second AC signal,
the phase synchronizing circuit includes a first phase synchronizing circuit and a second phase synchronizing circuit, the first phase synchronizing circuit being configured to generate the first AC signal, and the second phase synchronizing circuit being configured to generate the second AC signal,
the modulation circuit is configured to modulate the first AC signal by controlling an operation of the first phase synchronizing circuit, and is configured to modulate the second AC signal by controlling an operation of the second phase synchronizing circuit,
the wired transmission circuit is configured to transmit the result of the detection by the light detector by using one of the first AC signal and the second AC signal as the clock signal, and
the wireless transmission circuit is configured to transmit one of the first AC signal and the second AC signal modulated by the modulation circuit.
   (11)

The semiconductor device according to any one of (1) to (10), in which
the result of the detection by the light detector includes image data of a captured image.
   (12)

The semiconductor device according to any one of (1) to (10), in which
the result of the detection by the light detector includes image data of a distance image.
   (13)

The semiconductor device according to any one of (1) to (12), in which
the light detector is provided on a first semiconductor chip, and
the wired transmissions circuit is provided on a second semiconductor substrate attached to the first semiconductor chip.
   (14)

The semiconductor device according to (13), in which
the wireless transmission circuit includes an amplification circuit and a matching circuit, and
at least a part of the matching circuit is provided on the first semiconductor chip.
   (15)

The semiconductor device according to (14), in which
the matching circuit includes an inductor, and
the inductor is provided on the first semiconductor chip.

This application claims priority based on Japanese Patent Application No. 2021-151594 filed on Sep. 16, 2021 with Japan Patent Office, the entire contents of which are incorporated in this application by reference.

It should be understood by those skilled in the art that various modifications, combinations, sub-combinations and alterations may occur depending on design requirements and other factors insofar as they are within the scope of the appended claims or the equivalents thereof.

1. A semiconductor device, comprising:
a light detector including a plurality of light-receiving pixels configured to detect light;
a phase synchronizing circuit configured to generate an AC signal;
a modulation circuit configured to modulate the AC signal by controlling an operation of the phase synchronizing circuit;
a wired transmission circuit configured to transmit a result of the detection by the light detector by using the AC signal as a clock signal; and
a wireless transmission circuit configured to transmit the AC signal modulated by the modulation circuit.

2. The semiconductor device according to claim 1, wherein
the light detector is configured to repeatedly perform a light detection operation on a basis of a frame period as a unit,
the modulation circuit is configured to modulate the AC signal by controlling the operation of the phase synchronizing circuit on a basis of the result of the detection by the light detector, and
the wireless transmission circuit is
configured to transmit the AC signal modulated by the modulation circuit, and
configured to operate during a first period and configured to stop operating during a second period, the first period including one or a plurality of periods out of the frame period, and the second period being out of the frame period and other than the first period.

3. The semiconductor device according to claim 2, wherein
the first period includes a period in which the light detection operation is not performed.

4. The semiconductor device according to claim 2, further comprising a plurality of output terminals, wherein
the wireless transmission circuit includes a plurality of transmission circuits led to the respective plurality of output terminals.

5. The semiconductor device according to claim 1, further comprising a wireless reception circuit, wherein
the modulation circuit is configured to modulate the AC signal, the modulation circuit modulating the AC signal by controlling the operation of the phase synchronizing circuit on a basis of a first predetermined signal,
the wireless transmission circuit is configured to transmit the AC signal modulated by the modulation circuit, and
the wireless reception circuit is configured to receive a signal that is based on the AC signal transmitted by the wireless transmission circuit.

6. The semiconductor device according to claim 5, further comprising:
a plurality of output terminals; and
a plurality of input terminals, wherein
the wireless transmission circuit includes a plurality of reception circuits led to the respective plurality of output terminals, and
the wireless reception circuit includes a plurality of reception circuits led to the respective plurality of input terminals.

7. The semiconductor device according to claim 1, wherein
the wireless transmission circuit is configured to change an amplitude of the AC signal to be transmitted, and
the modulation circuit is further configured to modulate an amplitude of an output signal of the wireless transmission circuit by controlling an operation of the wireless transmission circuit.

8. The semiconductor device according to claim 1, wherein
the modulation circuit is configured to modulate the AC signal, the modulation circuit modulating the AC signal by controlling the operation of the phase synchronizing circuit on a basis of a second predetermined signal, and
the wired transmission circuit is configured to transmit the result of the detection by the light detector by using the AC signal as the clock signal, the AC signal being modulated by the modulation circuit.

9. The semiconductor device according to claim 1, further comprising an output terminal led to the wired transmission circuit and to the wireless transmission circuit, wherein
the wired transmission circuit and the wireless transmission circuit are configured to operate exclusively.

10. The semiconductor device according to claim 1, wherein
the AC signal includes a first AC signal and a second AC signal,
the phase synchronizing circuit includes a first phase synchronizing circuit and a second phase synchronizing circuit, the first phase synchronizing circuit being configured to generate the first AC signal, and the second phase synchronizing circuit being configured to generate the second AC signal,
the modulation circuit is configured to modulate the first AC signal by controlling an operation of the first phase synchronizing circuit, and is configured to modulate the second AC signal by controlling an operation of the second phase synchronizing circuit,
the wired transmission circuit is configured to transmit the result of the detection by the light detector by using one of the first AC signal and the second AC signal as the clock signal, and
the wireless transmission circuit is configured to transmit one of the first AC signal and the second AC signal modulated by the modulation circuit.

11. The semiconductor device according to claim 1, wherein
the result of the detection by the light detector includes image data of a captured image.

12. The semiconductor device according to claim 1, wherein
the result of the detection by the light detector includes image data of a distance image.

13. The semiconductor device according to claim 1, wherein
the light detector is provided on a first semiconductor chip, and
the wired transmissions circuit is provided on a second semiconductor substrate attached to the first semiconductor chip.

14. The semiconductor device according to claim 13, wherein
the wireless transmission circuit includes an amplification circuit and a matching circuit, and
at least a part of the matching circuit is provided on the first semiconductor chip.

15. The semiconductor device according to claim 14, wherein
the matching circuit includes an inductor, and
the inductor is provided on the first semiconductor chip.
